(19) United States
(12) Patent Application Publication
(10) Pub. No.: US 2026/0068107 A1
(43) Pub. Date: Mar. 5, 2026

(54) ALLOY AND METHODS FOR USING ALLOY FOR TRANSIENT LIQUID PHASE SINTERING

(71) Applicant: Dana Canada Corporation, Oakville (CA)

(72) Inventor: Andrei CATUNEANU, Burlington (CA)

(21) Appl. No.: 18/817,836

(22) Filed: Aug. 28, 2024

(51) Int. Cl. H05K 7/20; C22C 1/04; C22C 28/00

(52) U.S. Cl. CPC H05K 7/20854; C22C 1/0483; C22C 28/00; H05K 7/20481

(57) ABSTRACT

A method for forming a thermally conductive metallurgic joint, comprising: applying a liquid filler metal alloy comprising 76-90 wt. % gallium and 10-24 wt. % tin to a first surface and a second surface; placing the first surface and second surface in relative positions to form an assembly; and heating the assembly and holding the assembly at an approximately constant temperature for a non-zero duration of time to form the thermally conductive metallurgic joint.

### TECHNICAL FIELD

The present description relates to a system and a method of manufacture for physically and thermally coupling a heat exchanger and a power electronic component.

### BACKGROUND AND SUMMARY

Electrically powered devices and systems, such as power electronics for electric vehicles (EVs), may generate waste heat. To reduce degradation to power electronics from thermal energy, cooling and removal of waste heat may be accomplished through direct bonding to a cooler, where one or more of a plurality of power electronics may be metallurgically bonded to the cooler. More specifically, one or more first parent surfaces of an electrically powered device or system may metallurgically bond to at least a second parent surface of a cooler. Direct bonding may decrease the thermal resistance by orders of magnitude compared to thermal interface materials (TIMs), such as greases, dielectric pads, thermal tapes, or gels, allowing for waste heat from an electrical powered device or system to be removed in greater quantities and faster rates via the cooler.

The inventors herein have recognized issues when direct bonding electric vehicle traction inverters and other electrical power devices and systems to coolers. High pressures and high temperatures used to metallurgically bond the electrical powered device to the cooler may cause degradation to power electronics. Further, specific materials, such as silver (Ag), used in the process may be scarce.

For example, power electronics may degrade when exposed to temperatures greater than 250° C. and pressures greater than 20 MPa. In the pressure silver sintering process, a paste or preform of Ag sinter material may be sintered at approximately 200° C.-250° C. between pressures of 10 MPa-20 MPa. However, Ag sinter material may be scarcer compared to more common sintering and soldering metals. Additionally, silver sintering is a batch process, decreasing throughput compared to soldering. Pressure silver sintering may be restricted to joints with a surface area less than approximately 30 millimeters (mm)×30 mm square, which may be too small for larger electronic components. Further, pastes and pre-forms for soldering or sintering are often combined with chemical fluxes carried in binders to clean the joining surfaces prior to soldering; however, these fluxes and binders vaporize during the solder process, leading to voids in the metallurgic joint which are deleterious to heat transfer and durability.

Recognizing the above issues, the inventors herein have developed various approaches to at least partially address them. In an example, a method for forming a thermally conductive metallurgic joint comprises applying a liquid filler metal alloy comprising 76-90 wt. % gallium (Ga) and 10-24 wt. % tin (Sn) to a first surface and a second surface; placing the first surface and second surface in relative positions to form an assembly; and heating the assembly and holding the assembly at an approximately constant temperature for a non-zero duration of time to form the thermally conductive metallurgic joint. Using the method, liquid filler metal alloy may be solidified into a joint through transient liquid phase sintering (TLPS). The method may be used to join a heat exchanger electronic assembly via the thermally conductive metallurgic joint, wherein the electronics components may be thermally coupled and physically coupled via metallurgic bonds. Further the method may increase tensile strength, compressive strength, and resistance to shearing of the thermally conductive metallurgic joint. Additionally, metallurgic joints may be joined and bonded via TLPS without causing degradation to the electronic component or heat exchanger by keeping temperature below a first threshold of 250° C. and pressures below a second threshold of 20 MPa while joining and bonding via TLPS.

After solidification via joining through TLPS, the solid joint may comprise 20-50 wt. % Ga and up to 10 wt. % Sn. After solidification, the solid joint may comprise 20-80 wt. % Cu. The additional wt. % of Cu may be from the parent surfaces, foil surfaces, and/or from copper particles interspersed in the joint.

The method may also be used with a plurality of configurations of TLPS joints. An additional configuration of the TLPS joint may be a composite incorporating layers of metallic foil, such as Cu foil, each interspersed between two sub layers of GaSn alloy. Another additional or alternative configuration includes TLPS joint of GaSn alloy with metal particles, such as Cu particles, as an additive.

It should be understood that the summary above is provided to introduce in simplified form a selection of concepts that are further described in the detailed description. It is not meant to identify key or essential features of the claimed subject matter, the scope of which is defined uniquely by the claims that follow the detailed description. Furthermore, the claimed subject matter is not limited to implementations that solve any disadvantages noted above or in any part of this disclosure.

### BRIEF DESCRIPTION OF THE FIGURES

FIG. 1A shows a schematic of a joint of the present disclosure before transient liquid phase sintering (TLPS).

FIG. 1B shows a schematic of the joint assembly after TLPS.

FIG. 2 shows a schematic of a joint of the present disclosure after TLPS.

FIG. 3A shows a schematic of a joint of the present disclosure after TLPS.

FIG. 3B shows as schematic of a joint of the present disclosure after TLPS.

FIG. 4 shows a schematic of a joint of the present disclosure after TLPS.

FIG. 5 shows a schematic of a joint of the present disclosure after TLPS.

FIG. 6 shows a schematic of a heat exchanger electronic assembly comprising a plurality of electronic components physically and thermally coupled to a cooler via a plurality of joints of the present disclosure.

FIG. 7 shows a schematic of a plurality of features and components of an electronic component physically and thermally coupled to the cooler via a joint of the present disclosure.

FIG. 8 shows a method for constructing, and joining and bonding a first joint via TLPS to physically and thermally couple a cooler and an electronic component.

FIG. 9 shows a method for constructing, joining and bonding a second joint via TLPS to physically and thermally couple a cooler and an electronic component.

FIG. 10 shows a schematic of a vehicle including a cooling circuit that comprises a heat exchanger and at least an electronic component of the present disclosure.

### DETAILED DESCRIPTION

The description relates to a system and method to manufacture an assembly of a heat exchanger paired with one or more electrical components. The heat exchanger may be a cooler that may cool the electrical components physically and thermally coupled thereto. More specifically, the description relates to a method of manufacturing a thermally conductive metallurgic joint between a first parent layer of the heat exchanger and a second parent layer of the electrical component via fixing a liquid filler metal alloy between the first parent layer and the second parent layer, and then joining and bonding to the filler metal alloy after solidification of the alloy through a heat treatment.

The liquid filler metal alloy is applied to a first surface of the first parent layer and/or a second surface of the second parent layer, and sandwiched in a gap between the first surface and second surface prior to bonding. The first parent layer and the second parent layer are metallic. One or more electrical components are physically and thermally coupled to the heat exchanger via the metallurgic joint. The joining and bonding technique of the method is transient liquid phase sintering (TLPS). During TLPS, the liquid filler metal alloy from the metallurgic joint is joined and diffuses via inter-diffusion into the parent layers of the electronic component(s) and the heat exchanger. The liquid filler metal alloy may comprise gallium (Ga) and tin (Sn). During the method, one or more electronic components and the heat exchanger may be fixed and clamped together via a fixture assembly to form the gap and sandwich the liquid filler metal alloy between the first surfaces of the electronic components and one or more second surfaces of the heat exchanger before being joined.

The method of manufacture of the assembly of the heat exchanger, the electronic components, and the metallurgic joint via TLPS and the liquid filler metal alloy may have a plurality of advantages. For example, the process temperature of the method may be below power electronics thermal limits, where joining and bonding via the liquid filler metal alloy may occur between temperatures of 150° C. and 200° C. for example. The TLPS process is isothermal (e.g., holding the assembly at an approximately constant temperature) and may be continued over non-zero duration of time such that the alloy diffuses into the first and second parent layers to form a solid joint. approximately constant temperature may refer to being +/−5% of being at a given temperature over a period of time. The non-zero duration of time may be greater than 0.5 hours (hrs) and less than 4 hrs, for example. Additionally, the metallurgic joint may be joined and bonded to parent surfaces of the parent layers at low pressures, where the joint may be joined and bonded at pressures below 20 MPA, for example. Further, the joint may be joined and bonded to parent surfaces at pressures below 15 MPA.

When joined and bonded via TLPS, GaSn alloy may be used for joints covering areas greater than 30 mm×30 mm, for example. However, it should be appreciated that the sizing of the area of the joints may be non-limiting, and the GaSn alloy may cover, join, and bond to areas that are smaller than 30 mm×30 mm. Likewise, the method of manufacture may be executed when there is no desire for fluxes and no fluxes used throughout the process for the filler alloy, for example. Further still, the bond line thickness of thermally conductive metallurgic joint may be thinner than compared to a joint formed via soldering, lowering thermal resistance. For example, the bond line thickness of a TLPS formed thermally conductive metallurgic joint may be between 150 and 250 microns in thickness, and a joint formed via soldering methods of prior art may be between 200 and 300 microns. Further still, the thermal conductivity of the GaSn alloys after solidifying into a solid joint is at least double that of a solder. In an example, the coefficient of thermal expansion of the joint may be made similar to the parent materials for improved durability. For example, copper (Cu) may be used for the first and second parent layers, where a first parent surface of the first parent layer and a second parent surface of the second parent layer comprise Cu. The GaSn alloy has a coefficient of thermal expansion closer to Cu compared to sintering and soldering material of prior art, such as lead (Pb) or silver (Ag) sintering materials, such as metals or alloys. GaSn alloy and its derivatives may be produced with greater throughput compared to Ag sinter materials.

The description also relates to a plurality of example configurations of TLPS joints that may be created for the assembly. For example, a configuration of the TLPS joint may comprise the GaSn alloy joined and metallurgically bonded to a first parent surface of an electronic component and a second parent surface of the heat exchanger via a method of TLPS. The first and second parent surfaces may be a thermally conductive metal and may be the same metal, such as Cu. For another example, another TLPS joint may be between the first parent layer comprising a metal and a second parent layer comprising a material with plating, where the material is less compatible or un-compatible with metallurgic bonding to the GaSn alloy and the plating is compatible with metallurgic bonding to the GaSn alloy. For example, a second parent layer may have a core of aluminum (Al) less compatible or un-compatible with the GaSn alloy and a plating of nickel (Ni) compatible with the GaSn alloy. For another example, of the TLPS joint may be a configuration that may be a composite incorporating layers of metallic foil, such as Cu foil, each interleaved between layers of the GaSn alloy. For this or another example, TLPS joint may be of a configuration where the GaSn alloy includes metal particles, such as Cu particles, as an additive.

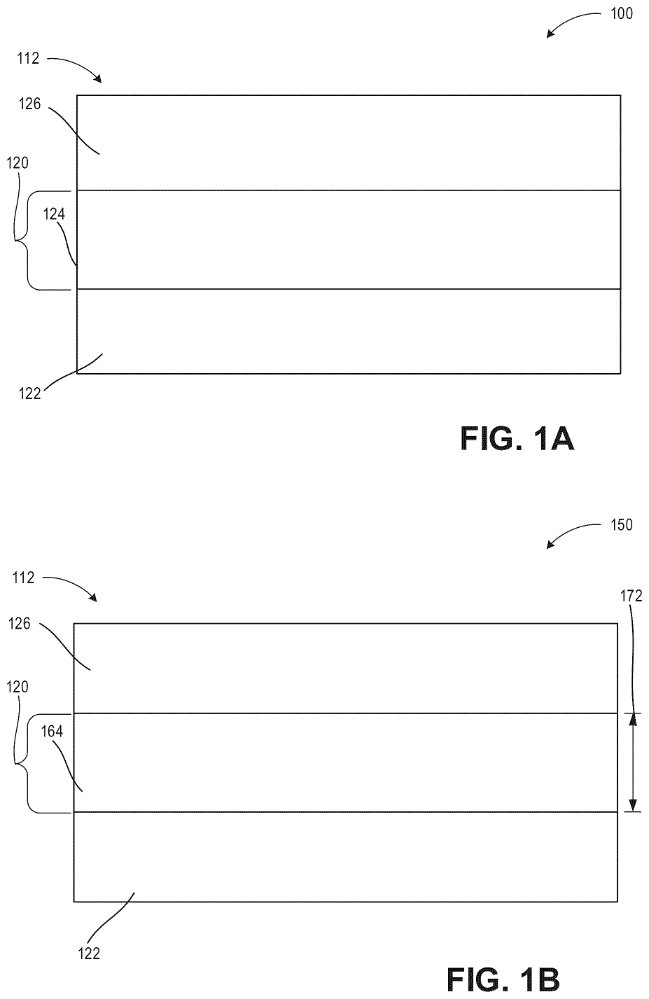

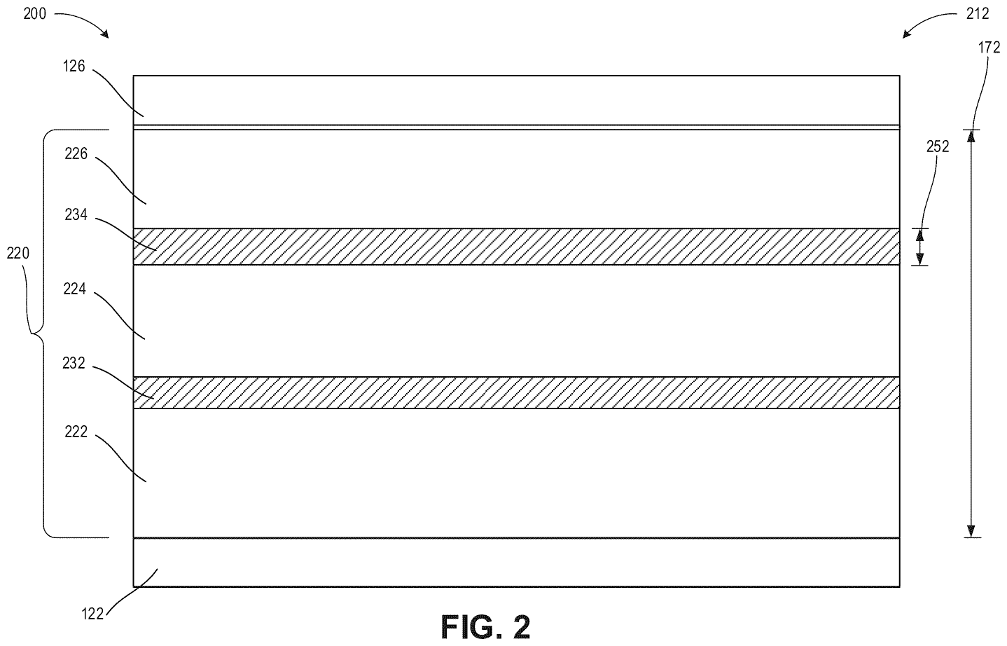

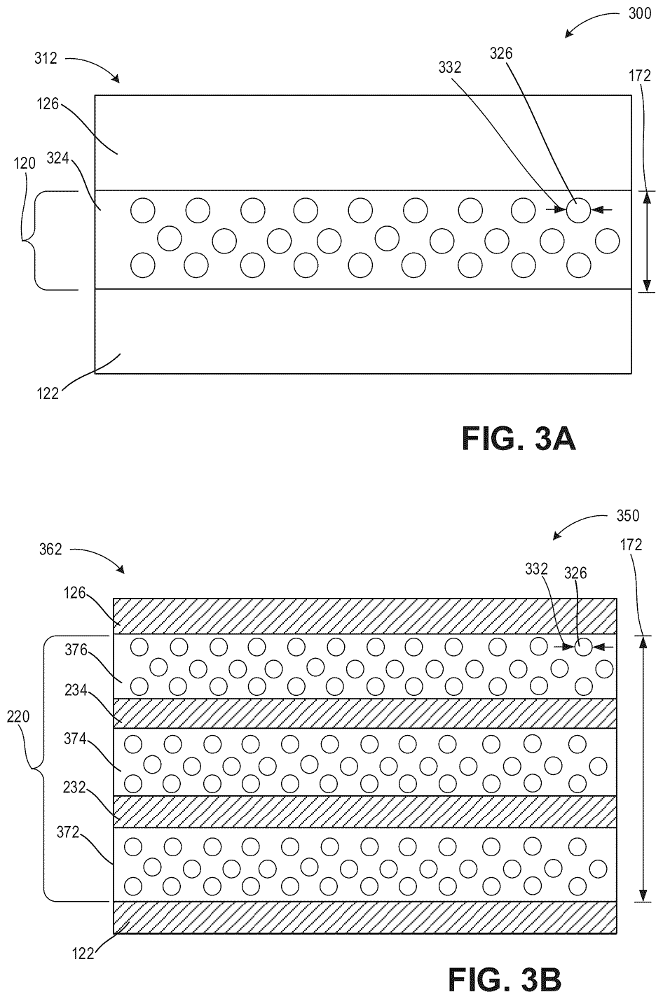

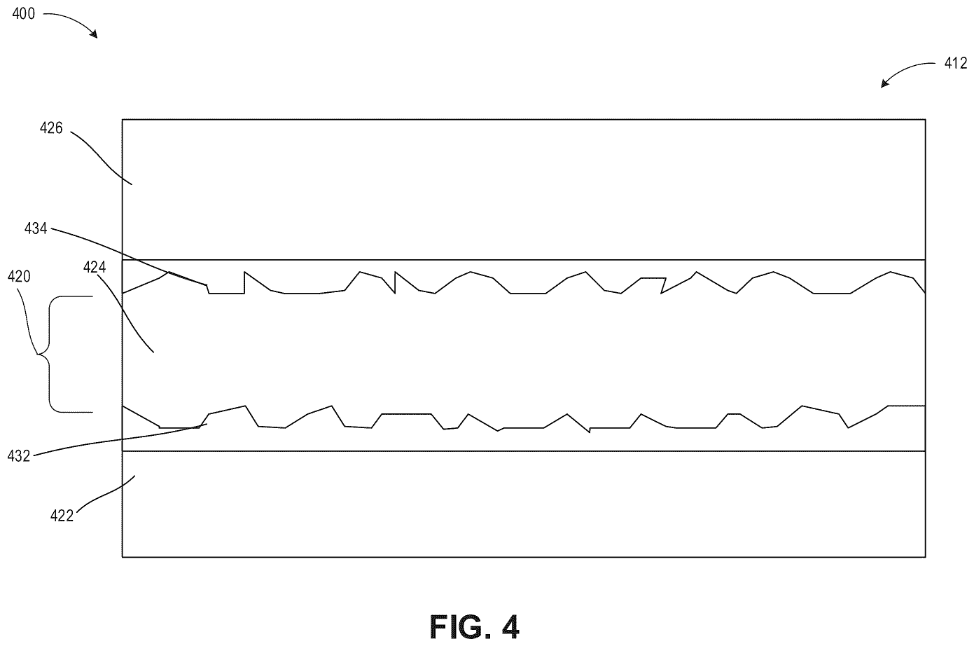

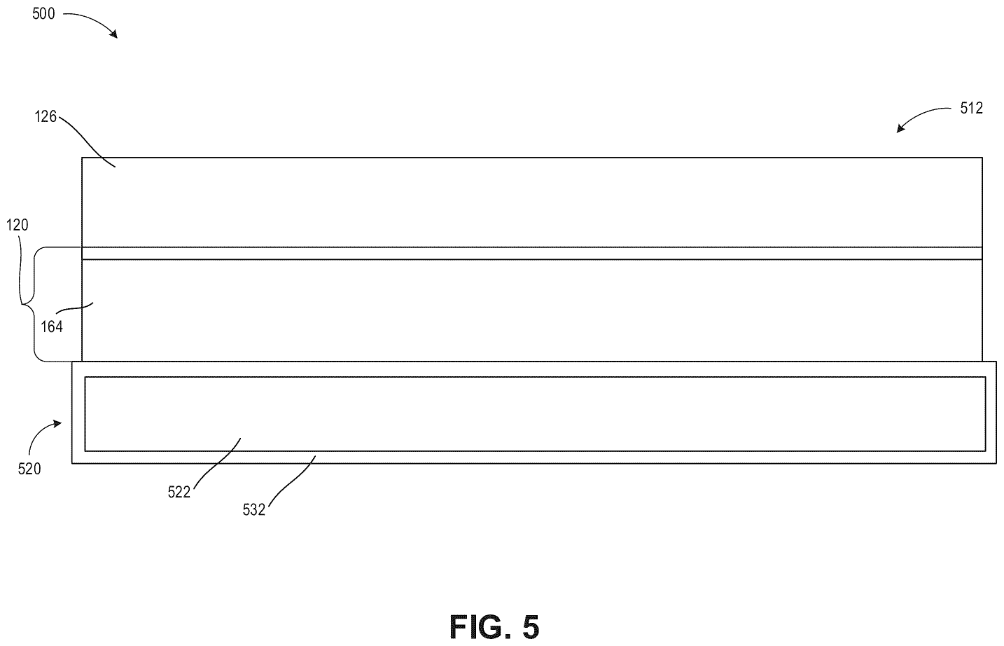

FIG. 1A shows a schematic of a first example configuration of a joint of the present disclosure before being joined and bonded via TLPS. FIG. 1B shows a schematic of a first example configuration of the joint of the present disclosure after being joined and bonded via TLPS. The first example configuration of the joint of FIGS. 1A-1B includes an alloy of the present disclosure between the first parent surface of the electronic component and the second parent surface of the heat exchanger. FIG. 2 shows a schematic of a second example configuration of the joint of the present disclosure after being joined and bonded via TLPS. The second configuration of the joint of FIG. 2 is a composite between the first and second parent surface, incorporating a plurality of layers of metallic foil each interspersed between two sub layers of the alloy. FIG. 3A and FIG. 3B show a schematic of a third example configuration of the joint and a fourth example configuration of the joint of the present disclosure after being joined and bonded via TLPS. FIG. 3A shows a single layer of the alloy as a joint similar to the first configuration of FIGS. 1A-1B, where the alloy includes metal particles as an additive. FIG. 3B shows a plurality of layers of the alloy part of a composite similar to the second configuration of FIG. 2, where the alloy includes metal particles as additives. FIG. 4 shows a schematic of a fifth example configuration of a joint of the present disclosure after being joined and bonded via TLPS, where the first parent surface and the second parent surface are rough surfaces. FIG. 5 shows a schematic of a sixth example configuration of a joint of the present disclosure after being joined and bonded via TLPS. The joint of the sixth example configuration of FIG. 5 is bonded to a parent layer is a first material plated with a second material, where the first material is less compatible with metallurgic bonding to the GaSn alloy and the plating of the second material is more compatible with metallurgic bonding to the GaSn alloy.

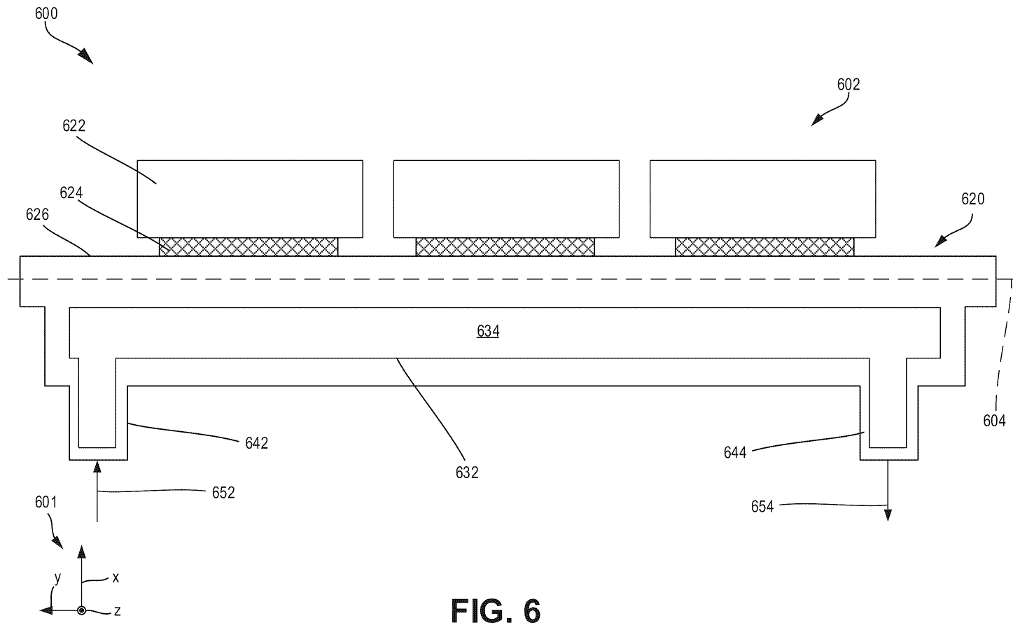

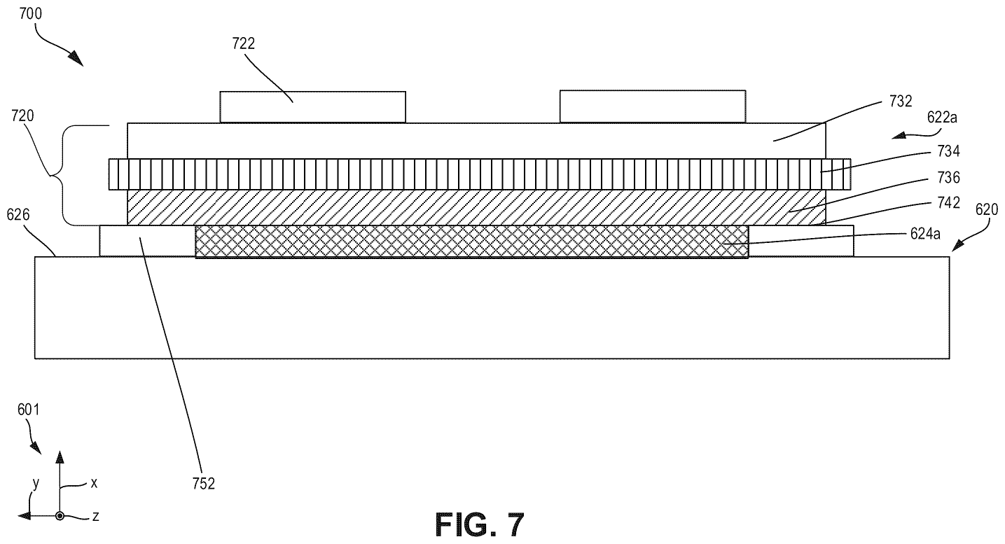

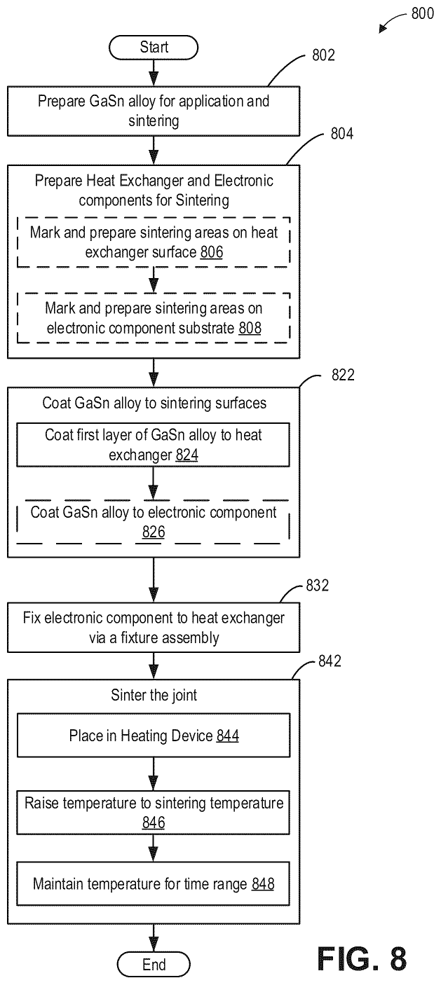

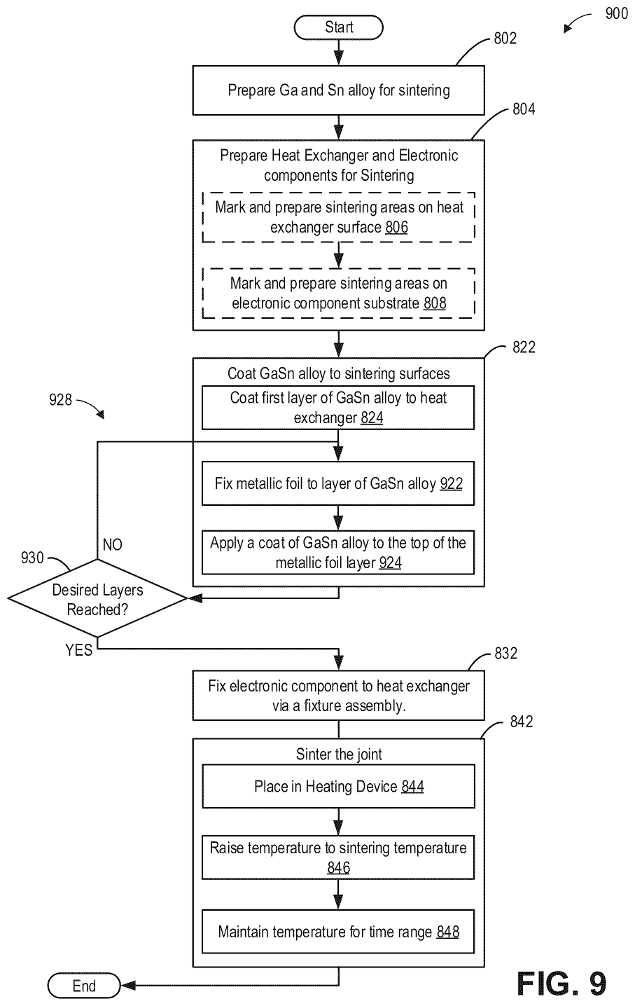

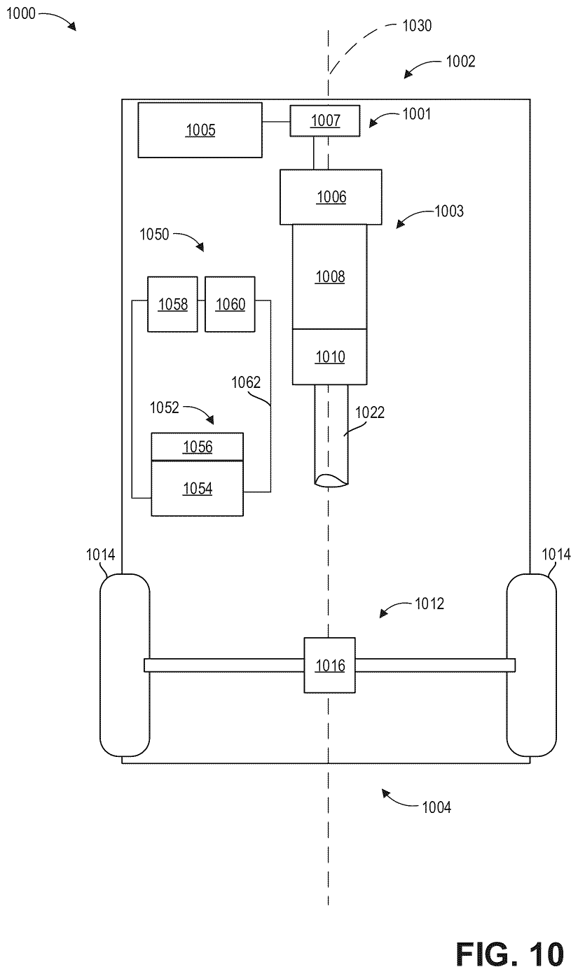

FIG. 6 shows a schematic of a heat exchanger electronic assembly comprising a plurality of joints of the present disclosure. The heat exchanger electronic assembly of FIG. 6 includes a heat exchanger and a plurality of electronic components joined and bonded via the joints. The electronic components of FIG. 6 may be electronic assemblies and, more specifically, be or include power electronic components. FIG. 7 shows a schematic of a plurality of features and components of an electronic component physically and thermally coupled to the heat exchanger via a joint of the present disclosure. The electronic component of FIG. 7 may be one of the electronic components of FIG. 6, and the joint of FIG. 7 may be one of the joints of FIG. 6. The cooler of FIG. 6 and FIG. 7 may be a heat exchanger. FIG. 8 shows a method for constructing, and joining and bonding a first joint via TLPS to physically and thermally couple a cooler and an electronic component. The first joint of FIG. 8 is a layer of GaSn alloy, such as the first configuration FIGS. 1A-1B, the third configuration of FIG. 3A, the fifth configuration of FIG. 4, or the sixth configuration of FIG. 5. FIG. 9 shows a method for constructing, joining and bonding a second joint via TLPS to physically and thermally couple a cooler and an electronic component. The second joint of FIG. 9 is a composite of at least a layer of foil and a plurality of GaSn alloy layers, such as the second configuration shown in FIG. 2 or the fourth configuration shown in FIG. 3B. FIG. 10 shows a schematic of a vehicle including a cooling circuit that comprises a heat exchanger and at least an electronic component of the present disclosure.

It is also to be understood that the specific assemblies and systems illustrated in the attached drawings, and described in the following specification are exemplary embodiments of the inventive concepts defined herein. For purposes of discussion, the drawings are described collectively. Thus, like elements may be commonly referred to herein with like reference numerals and may not be re-introduced.

FIGS. 1A-7 and FIG. 10 show example configurations with relative positioning of the various components. If shown directly contacting each other, or directly coupled, then such elements may be referred to as directly contacting or directly coupled, respectively, at least in one example. Similarly, elements shown contiguous or adjacent to one another may be contiguous or adjacent to each other, respectively, at least in one example. As an example, components laying in face-sharing contact with each other may be referred to as in face-sharing contact. As another example, elements positioned apart from each other with only a space there-between and no other components may be referred to as such, in at least one example. As yet another example, elements shown above/below one another, at opposite sides to one another, or to the left/right of one another may be referred to as such, relative to one another. Further, as shown in the figures, a topmost element or point of element may be referred to as a “top” of the component and a bottommost element or point of the element may be referred to as a “bottom” of the component, in at least one example. As used herein, top/bottom, upper/lower, above/below, may be relative to a vertical axis of the figures and used to describe positioning of elements of the figures relative to one another. As such, elements shown above other elements are positioned vertically above the other elements, in one example. As yet another example, shapes of the elements depicted within the figures may be referred to as having those shapes (e.g., such as being circular, straight, planar, curved, rounded, chamfered, angled, or the like). Further, elements shown intersecting one another may be referred to as intersecting elements or intersecting one another, in at least one example. Further still, an element shown within another element or shown outside of another element may be referred as such, in one example. Moreover, the components may be described as they relate to reference axes included in the drawings.

Turning to FIG. 1A, it shows a schematic 100 of a first joint assembly 112. The first joint assembly 112 is an example of a first configuration of a joint assembly of the present disclosure. The schematic 100 shows the first joint assembly 112 before being joined and bonded via TLPS.

The first joint assembly 112 comprises a joint section 120 sandwiched between a first parent layer 122 and a second parent layer 126. When joined, the joint section 120 forms a metallurgic joint between the first parent layer 122 and the second parent layer 126, where the metallurgic joint thermally couples and physically couples the first parent layer 122 and the second parent layer 126. The first parent layer 122 and the second parent layer 126 may be layers of a first metal and a second metal, respectively, that are thermally conductive metals with smooth surfaces contacting the joint section 120. The first metal of the first parent layer 122 and the second metal of the second parent layer 126 may be the same metal. For an example, the first parent layer 122 and the second parent layer 126 are formed of smooth copper (Cu). The first parent layer 122 and the second parent layer 126 may be part of a feature of a heat exchanger or an electronic component/assembly. For example, the first parent layer 122 and the second parent layer 126 may be a metal ends of a heat exchanger and an electronic component, respectively.

Joint sections of the present disclosure comprise at least a layer of filler metal alloy to join the parent surfaces. For example, before being joined and bonded via TLPS, the first joint section 120 may comprise singular layer of a liquid filler metal alloy referred to herein as a liquid alloy layer 124. The liquid alloy layer 124 may have surface sharing contact with the first parent layer 122 and the second parent layer 126.

The liquid filler metal alloy of the liquid alloy layer 124 may be applied as a liquid coating to the first parent layer 122 and/or the second parent layer 126, such as via spreading. The liquid filler metal alloy of the liquid alloy layer 124 may be a paste. Additionally, the liquid filler metal alloy may lack chemical fluxes. The absence of chemical fluxes may reduce the formation of voids, such as from evaporation of the chemical fluxes, in the liquid filler metal alloy after joining and bonding. Said in another way, the absence of chemical fluxes from the liquid metal alloy of the liquid alloy layer 124 may reduce the formation of voids throughout the joint section 120. The liquid alloy layer 124 is sandwiched between a first surface of the first parent layer 122 and a second surface of the second parent layer 126 with no other materials therebetween.

The liquid filler metal alloy of liquid alloy layer 124 may be a GaSn alloy. The liquid filler metal alloy may have weight percent (wt. %) of Sn of a first range between 4-24 wt. % Sn. Additionally, the liquid metal alloy may have a wt. % of Ga of a second range between 76-96 wt. % Ga. The wt. % ranges of the Ga and Sn allow for the liquid filler metal alloy to be liquid at room temperature. For a first example, it may be desired for the liquid filler metal alloy to have the first range and second range of be narrower wt. % s, with the first range of wt. % for Sn being between 10-24 wt. % Sn, and the second range of Ga being between 76-90 wt. % Ga. For a second example, it may be desired for the liquid filler metal alloy to have the first range and second range of be narrower wt. % s, with the first range of wt. % for Sn being between 10-14 wt. % Sn, and the second range of Ga being between 86-90 wt. % Ga. Additionally, the first and second ranges may be narrower wt. % s. For example, the filler metal alloy may have the first range at or between 10-11 wt. % Sn and the second range at or between 89-90 wt. % Ga. For another example, the filler metal alloy may have the first range at or between 11-12 wt. % Sn and the second range at or between 88-89 wt. % Ga. For another example, the filler metal alloy may have the first range at or between 12-13 wt. % Sn and the second range at or between 87-88 wt. % Ga. For another example, the filler metal alloy may have the first range at or between 13-14 wt. % Sn and the second range at or between 86-87 wt. % Ga.

The liquid filler metal alloy may lack chemical fluxes carried in binders, preventing the formation of bubbles or other voids in the metal alloy due to evaporation of the chemical fluxes while joining or bonding. Voids may increase resistance to heat transfer across the filler metal alloy and decrease durability and shear strength of the filler metal alloy.

Turning to FIG. 1B, a schematic 150 of the first joint assembly 112 after joining and bonding via TLPS. Schematic 150 shows the first joint section 120 joined and bonded via TLPS into a solid joint.

Layers of liquid filler metal alloy may be joined into layers of solid filler metal alloy via TLPS. To joining and/or bonding surfaces via TLPS may be performed at temperatures at or between the range of 150° C. and 250° C. in an atmosphere of inert gas at a pressure below 20 MPa for a non-zero duration of time. The non-zero duration of time may be greater than 0.5 hrs (30 minutes) and less than 4 hrs. For example, there may be a desire to sinter via TLPS at a temperature between a narrower range joining and bonding temperatures at or between 150° C. and 200° C. Likewise, for this or other examples, the time for TLPS may be a range at or between 0.5 hrs-2 hrs. Joining and bonding via TLPS may be performed between 1 atmosphere (Atm) or 0.1013 MPa and 20 MPa. Likewise, for this or other examples, joining and bonding via TLPS may be performed between 0.1013 MPa and 10 MPa. The joining and bonding temperature may isothermal during TLPS. Said in another way, joining and bonding may be performed by holding the first joint assembly 112 or other join assemblies of the present disclosure at an approximately constant temperature during TLPS. The inert gas may be nitrogen (N2).

The range of joining and bonding temperatures narrower than the previous examples. For another example, the range of joining and bonding temperatures may be at or between 150° C. and 160° C. For another example, the range of joining and bonding temperatures may be at or between 160° C. and 170° C. For another example, the range of joining and bonding temperatures may be at or between 170° C. and 180° C. For another example, the range of joining and bonding temperatures may be at or between 180° C. and 190° C. For another example, the range of joining and bonding temperatures may be at or between 190° C. and 200° C.

The range of pressure may be narrower than the previous examples. For another example, the range of pressures may beat or between 0.1013 MPa and 0.2 MPa. For another example, the range of pressures may be at or between 0.2 MPa and 0.5 MPa. For another example, the range of pressures may be at or between 0.5 MPa and 1 MPa. For another example, the range of pressures may be at or between 1 MPa and 2 MPa. For another example, the range of pressures may be between 2 MPa and 3 MPa. For another example, the range of pressures may be at or between 3 MPa and 4 MPa. For another example, the range of pressures may be at or between 4 MPa and 5 MPa. For another example, the range of pressures may be at or between 5 MPa and 6 MPa. For another example, the range of pressures may be at or between 6 MPa and 7 MPa. For another example, the range of pressures may be at or between 7 MPa and 8 MPa. For another example, the range of pressures may be at or between 8 MPa and 9 MPa. For another example, the range of pressures may be at or between 9 MPa and 10 MPa. For another example, the range of pressures may be at or between 10 MPa and 12 MPa. For another example, the range of pressures may be at or between 12 MPa and 14 MPa. For another example, the range of pressures may be at or between 14 MPa and 16 MPa. For another example, the range of pressures may be at or between 16 MPa and 18 MPa. For another example, the range of pressures may be at or between 18 MPa and 19 MPa. For another example, the range of pressures may be at or between 19 MPa and 20 MPa.

The range of joining and bonding times may be narrower than the previous examples. For another example, the range joining and bonding times may be 0.5 hrs-0.6 hrs. For another example, the range of joining and bonding times may be 0.6 hrs-0.7 hrs. For another example, the range of joining and bonding times may be 0.6 hrs-0.7 hrs. For another example, the range of joining and bonding times may be 0.7 hrs-0.8 hrs. For another example, the range of joining and bonding times may be 0.9 hrs-1 hr. For another example, the range of joining and bonding times may be 1 hr-1.1 hrs. For another example, the range of joining and bonding times may be 1.1 hrs-1.2 hrs. For another example, the range of joining and bonding times may be 1.2 hrs-1.3 hrs. For another example, the range of joining and bonding times may be 1.3 hrs-1.4 hrs. For another example, the range of joining and bonding times may be 1.4 hrs-1.5 hrs. For another example, the range of joining and bonding times may be 1.5 hrs-1.6 hrs. For another example, the range of joining and bonding times may be 1.6 hrs-1.7 hrs. For another example, the range of joining and bonding times may be 1.7 hrs-1.8 hrs. For another example, the range of joining and bonding times may be 1.8 hrs-1.9 hrs. For another example, the range of joining and bonding times may be 1.9 hrs-2 hrs.

Upon being joined and bonded via TLPS, the joint section 120 may comprise a solid alloy layer 164 as the singular layer filler metal alloy. The liquid alloy layer 124 of FIG. 1A is solidified into the solid alloy layer 164 via TLPS. The liquid alloy layer 124 of FIG. 1A may also be joined and bonded to the first parent layer 122 and the second parent layer 126. Additionally, when joined and bonded, the solid alloy layer 164 may be metallurgically bonded to the first parent layer 122 and the second parent layer 126. Upon being joined and bonded via TLPS, the solid alloy layer 164 is decreased to a first thickness 172. The first thickness 172 may be between 150 and 250 microns. Upon solidification, joining, and bonding via TLPS, the first joint section 120 may therein be metallurgic joint section.

The joint section 120 and the solid alloy layer 164 may have wt. % of Sn of a third range up to 10 wt. % Sn after forming a joint via TLPS. Additionally, the joint section 120 and solid alloy layer 164 may have a wt. % of Ga of a fourth range between 20 wt. %-50 wt. % Ga after forming a joint via TLPS. Further the joint section 120 and solid alloy layer 164 may comprise copper (Cu), such as after joining and/or bonding via TLPS.

It may be desired for the solid alloy layer 164 to have the third range be of narrower wt. % s. For example, third range of wt. % for Sn may be between 0.1 wt. %-1 wt. % Sn. For another example, the third range of wt. % for Sn may be at or between 1 wt. %-1.5 wt. % Sn. For another example, the third range of wt. % for Sn may be at or between 1.5 wt. %-2 wt. % Sn. For another example, the third range of wt. % for Sn may be at or between 2 wt. %-3 wt. % Sn. For another example, the third range of wt. % for Sn may be at or between 3 wt. %-4 wt. % Sn. For another example, the third range of wt. % for Sn may be at or between 4 wt. %-5 wt. % Sn. For another example, the third range of wt. % for Sn may be at or between 5 wt. %-6 wt. % Sn. For another example, the third range of wt. % for Sn may be at or between 6 wt. %-7 wt. % Sn. For another example, the third range of wt. % for Sn may be at or between 7 wt. %-8 wt. % Sn. For another example, the third range of wt. % for Sn may be at or between 8 wt. %-9 wt. % Sn. For another example, the third range of wt. % for Sn may be at or between 9 wt. %-10 wt. % Sn.

It may be desired for the solid alloy layer 164 to have the fourth range be of narrower wt. % s. For example, fourth range of wt. % for Ga may be at or between 20 wt. %-25 wt. % Ga. For another example, the fourth range of wt. % for Ga may be at or between 25 wt. %-30 wt. % Ga. For another example, the fourth range of wt. % for Ga may be at or between 30 wt. %-35 wt. % Ga. For another example, the fourth range of wt. % for Ga may be at or between 35 wt. %-40 wt. % Ga. For another example, the fourth range of wt. % for Ga may be at or between 40 wt. %-45 wt. % Ga. For another example, the fourth range of wt. % for Ga may be at or between 45 wt. %-50 wt. % Ga.

It may be desired for the solid alloy layer 164 to have the fifth range be of narrower wt. % s. For example, fifth range of wt. % for Cu may be at or between 55 wt. %-55 wt. % Cu. For another example, the fifth range of wt. % for Cu may be at or between 55 wt. %-60 wt. % Cu. For another example, the fifth range of wt. % for Cu may be at or between 60 wt. %-65 wt. % Cu. For another example, the fifth range of wt. % for Cu may be at or between 65 wt. %-70 wt. % Cu. For another example, the fifth range of wt. % for Cu may be at or between 70 wt. % -75 wt. % Cu. For another example, the fifth range of wt. % for Cu may be at or between 75 wt. %-80 wt. % Cu.

Turning to FIG. 2, it shows a schematic 200 of a second joint assembly 212. The second joint assembly 212 is an example of a second configuration of a joint assembly of the present disclosure. The schematic 200 shows the second joint assembly 212 after joining and bonding via TLPS. The second configuration shown by the second joint assembly 212 includes a second joint section 220 sandwiched between a first parent layer 122 and a second parent layer 126.

The second joint section 220 includes a plurality of filler metal alloy layers comprised of filler metal alloy, referred to herein as alloy layers. The alloy layers may be separated by at least a first solid metallic layer, where the first solid metallic layer is sandwiched between alloy layers. More specifically, the second joint section 220 includes a plurality of GaSn alloy layers separated via one or more layers of solid metallic material. The solid metallic layers may be thin sheets of metallic material. One or more solid metallic layers may be interleaved between the GaSn alloy layers, where each pair of GaSn alloy layers are contacted and are separated by a solid metallic layer. The plurality of alloy layers may be separated by a plurality of solid metallic layers, with each of the solid metallic layers sandwiched between two alloy layers. Said in another way, another alloy layer added to the joint section has another solid metallic layer interleaved and sandwiched between the another alloy layer and a previous alloy layer. Said in another way, another solid metallic layer added to the joint section has a previous alloy layer sandwiched between the another solid metallic layer and a previous solid metallic layer, and has another alloy layer applied atop the another solid metallic layer.

The second joint section 220 may include a plurality of alloy layers, each separated by at least a metallic foil layer, where each of the one or more metallic foil layers is an example of the solid metallic layers. The metallic foil layers of the second joint section 220 may be comprised of Cu, and therein be a Cu foil.

For an example, the second joint section 220 comprises a first alloy layer 222, a second alloy layer 224, and a third alloy layer 226 that may be the layers of filler metal alloy. Likewise, the second joint section 220 may comprise a first foil layer 232 and a second foil layer 234 as the layers of metallic foil. The first and second foil layers 232, 234 may be interleaved between the first alloy layer 222, the second alloy layer 224, and the third alloy layer 226. The first alloy layer 222 may be sandwiched between the first parent layer 122 and the first foil layer 232. The first foil layer 232 may be sandwiched between the first alloy layer 222 and the second alloy layer 224. The second alloy layer 224 may be sandwiched between the first foil layer 232 and the second foil layer 234. The second foil layer 234 may be sandwiched between the second alloy layer 224 and the third alloy layer 226. The third alloy layer 226 may be sandwiched between the second foil layer 234 and the second parent layer 126. The absence of chemical fluxes from the liquid filler metal alloy of the first alloy layer 222, the second alloy layer 224, and the third alloy layer 226 may reduce the formation of voids throughout the second joint section 220.

The first alloy layer 222, the second alloy layer 224, and the third alloy layer 226 may be applied to surfaces as a liquid filler metal alloy, such as via spreading. For example, the first alloy layer 222 may be applied as a liquid to and have surface sharing contact with the first parent layer 122 before joining and bonding via TLPS. Likewise, the first alloy layer 222 may have surface sharing contact with first foil layer 232. The second alloy layer 224 may be applied as a liquid and have surface sharing contact with the first foil layer 232 before joining and bonding via TLPS. Likewise, the second alloy layer 224 may have surface sharing contact with the second foil layer 234. The third alloy layer 226 may be applied as a liquid and have surface sharing contact with the second parent layer 126 before joining and bonding via TLPS. Likewise, the third alloy layer 226 may have surface sharing contact with the second foil layer 234. However, it is to be appreciated that the third alloy layer 226 or another alloy layer between a top most parent layer and another foil layer, may be applied as a liquid to the foil layer before the parent layer. For another example, the third alloy layer 226 may be applied as a liquid to the second foil layer 234.

The first alloy layer 222, the second alloy layer 224, and the third alloy layer 226 may be joined and bonded via TLPS into solid alloy layers. When joined and bonded via TLPS, the first alloy layer 222 may be metallurgically bonded to the first parent layer 122. When sintered via TLPS, the third alloy layer 226 may be metallurgically bonded to the second parent layer 126. The first foil layer 232 may be sandwiched between the first alloy layer 222 and the second alloy layer 224. After joining and bonding via TLPS, the first foil layer 232 may be metallurgically bonded with the first alloy layer 222 and the second alloy layer 224. After joining and bonding via TLPS, the second foil layer 234 may be metallurgically bonded with the second alloy layer 224 and the third alloy layer 226. Upon solidification, joining, and bonding via TLPS, the second joint section 220 may therein be metallurgic joint section.

The foil layers of the second joint section 220, such as the first foil layer 232 and second foil layer 234, may decrease the time for the second joint section 220 to solidify during joining and bonding compared to the joint section 120 of FIG. 1A. Likewise, the inclusion of foil layers by the second joint section 220 may increase the shear strength of the second joint section 220 and the second joint assembly 212 compared to the joint section 120 and the first joint assembly 112 of FIGS. 1A-1B.

The second joint section 220 may be the first thickness 172. Each of the foil layers may be a second thickness 252. For example, the second thickness 252 may be between 0.0005 inches and 0.002 inches in distance.

Turning to FIG. 3A, it shows a fourth schematic 300 of a third joint assembly 312. The third joint assembly 312 is a third configuration of a joint assembly of the present disclosure. The third joint assembly 312 is similar to the first joint assembly 112; however, with an alloy layer 324 in place of the liquid alloy layer 124 or the solid alloy layer 164 of FIG. 1B. The alloy layer 324 is a filler metal alloy and, more specifically, a GaSn alloy may have a weight percent of Sn of a first range up to 24 wt. % and a weight percent of Ga of a second range from 20 wt. % to 50 wt. %. The weight percent of Sn in the alloy may be a smaller range such as a wt. % of Sn with a third range from 10 wt. % to 14 wt. %. Further the weight percent of Sn in the alloy may be another smaller range such as a fourth range up to 10 wt. %.

The alloy layer 324 is imbedded with plurality of metal particles 326. The metal particle may comprise a metal with a high thermal conductivity. For an example the metal particles may be Cu, and therein be Cu particles. The weight percent of metal particles 326, for example Cu particles, may be 50 wt. % to 80 wt. % of the liquid alloy. Each of the metal particles 326 may have a diameter 332, where the diameter 332 is less than 50 microns.

It may be desired for the liquid alloy of the alloy layer 324 to have the weight percent of metal particles 326 be a narrower range of wt. % for the liquid alloy. For another example, the metal particles 326 may be a wt. % between 50 wt. %-55 wt. % of the liquid alloy, where the metal particles may be Cu. For another example, the metal particles 326 may be a wt. % between 55 wt. %-60 wt. % of the liquid alloy, where the metal particles may be Cu. For example, the metal particles 326 may be a wt. % between 60 wt. %-65 wt. % of the liquid alloy, where the metal particles may be Cu. For another example, the metal particles 326 may be a wt. % between 65 wt. %-70 wt. % of the liquid alloy, where the metal particles may be Cu. For another example, the metal particles 326 may be a wt. % between 70 wt. %-75 wt. % of the liquid alloy, where the metal particles may be Cu. For another example, the metal particles 326 may be a wt. % between 75 wt. %-80 wt. % of the liquid alloy, where the metal particles may be Cu.

Turning to FIG. 3B, it shows a fifth schematic 350 of a fourth joint assembly 362. The fourth joint assembly 362 is a fourth configuration of a joint assembly of the present disclosure. The fourth joint assembly 362 is similar to the second joint assembly 212 of FIG. 2, however with a first alloy layer 372, a second alloy layer 374, and a third alloy layer 376 in place of the first alloy layer 222, the second alloy layer 224, and the third alloy layer 226 of FIG. 2. The first alloy layer 372, the second alloy layer 374, and the third alloy layer 376 comprise filler metal alloy; more specifically, the GaSn alloy. The GaSn alloy of the first alloy layer 372, the second alloy layer 374, and the third alloy layer 376 may have the same compositions as the third joint assembly 312 and alloy layer 324 of FIG. 3A.

The GaSn alloy the first alloy layer 372, the second alloy layer 374, and the third alloy layer 376 may have a weight percent of Sn of a first range up to 24 wt. % and a weight percent of Ga of a second range from 20 wt. % to 50 wt. %. The weight percent of Sn in the alloy may be a smaller range such as a wt. % of Sn with a third range from 10 wt. % to 14 wt. %. Further, the weight percent of Sn in the alloy may be another smaller range such as a fourth range up to 10 wt. %. The first alloy layer 372, the second alloy layer 374, and the third alloy layer 376 are embedded with the metal particles 326. The weight percent of metal particles 326, for example Cu particles, may be 50 wt. % to 80 wt. % of the liquid alloy.

It may be desired for the liquid alloy of the alloy layer 324 to have the weight percent of metal particles 326 be a narrower range of wt. % of the liquid alloy. For another example, the metal particles 326 may be a wt. % between 50 wt. %-55 wt. % of the liquid alloy, where the metal particles may be Cu. For another example, the metal particles 326 may be a wt. % between 55 wt. %-60 wt. % of the liquid alloy, where the metal particles may be Cu. For example, the metal particles 326 may be a wt. % between 60 wt. %-65 wt. % of the liquid alloy, where the metal particles may be Cu. For another example, the metal particles 326 may be a wt. % between 65 wt. %-70 wt. % of the liquid alloy, where the metal particles may be Cu. For another example, the metal particles 326 may be a wt. % between 70 wt. %-75 wt. % of the liquid alloy, where the metal particles may be Cu. For another example, the metal particles 326 may be a wt. % between 75 wt. %-80 wt. % of the liquid alloy, where the metal particles may be Cu.

The metal particles 326 of the alloy layer 324 of FIG. 3A may be dispersed through the liquid filler metal alloy in preparation phase before applying the liquid filler metal alloy to surfaces of features of the third joint assembly 312. Likewise, metal particles 326 of the first alloy layer 372, the second alloy layer 374, and the third alloy layer 376 of FIG. 3B may be dispersed through the liquid filler metal alloy in preparation phase before applying the liquid filler metal alloy to surfaces of features of the fourth joint assembly 362. The metal particles 326 may increase the speed at a which a liquid filler metal alloy of the present disclosure solidifies and forms metallurgic bonds with metal or metal alloy surfaces. For example, the metal particles 326 may decrease the time for the alloy layer 324 to solidify and form metallurgic bonds via joining and bonding compared to the solidification of the liquid alloy layer 124 of FIG. 1A into the solid alloy layer 164 of FIG. 1B. For another example, the metal particles 326 may decrease the time for the first alloy layer 372, the second alloy layer 374, and the third alloy layer 376 to solidify and form metallurgic bonds via joining and bonding compared to the first alloy layer 222, the second alloy layer 224, and the third alloy layer 226 of FIG. 2.

Turning to FIG. 4, it shows a sixth schematic 400 of a fifth joint assembly 412. The fifth joint assembly 412 is a fifth configuration of a joint assembly of the present disclosure.

The fifth joint assembly 412 comprises a joint section 420 sandwiched between a first parent layer 422 and a second parent layer 426. When joined, the joint section 420 forms a metallurgic joint between the first parent layer 422 and the second parent layer 426 that thermally couples and physically couples the first parent layer 422 and the second parent layer 426. Upon solidification, joining, and bonding via TLPS, the joint section 420 may therein be metallurgic joint section.

The joint section 420 comprises a filler metal alloy layer referred to herein as an alloy layer 424. For an example, the alloy layer 424 may have the same composition as the liquid alloy layer 124 and the solid alloy layer 164 of FIG. 1A. For another example, the alloy layer 424 may have the same composition as the alloy layer 324 of FIG. 3A, and therein may be embedded with metal particles 326 of FIG. 3A. Before joining and bonding via TLPS, the alloy layer 424 may be applied as a liquid coating to the first parent layer 422 and/or the second parent layer 426, such as via spreading. After joining and bonding via TLPS, the alloy layer 424 may be metallurgically bonded to the first parent layer 122 and the second parent layer 126.

Like the first parent layer 122 and the second parent layer 126 of FIG. 1A, the first parent layer 422 and the second parent layer 426 may be part of a feature of a heat exchanger or an electronic component/assembly. For an example the first parent layer 422 may comprise a surface of heat exchanger and the second parent layer 426 may comprise a surface of an electronic component. Additionally, like the first parent layer 122 and the second parent layer 126, the first parent layer 422 and the second parent layer 426 may be a first metal and a second metal respectively. The first parent layer 422 and the second parent layer 426 may comprise the same material. For example, the first metal and the second metal may be the same metal: Cu.

The first parent layer 422 and the second parent layer 426 have rough surfaces. For example, the first parent layer 422 has a first rough surface 432, and the second parent layer 426 has a second rough surface 434, each with jagged protrusions from and indentations into their respective parent layers. The first rough surface 432 and the second rough surface 434 face inward toward the alloy layer 424. Before joining and bonding via TLPS, the alloy layer 424 may have surface sharing contact with the first rough surface 432 and the second rough surface 434. The alloy layer 424 may fill the indentations and the other volumes between the protrusions of the first rough surface 432 and the second rough surface 434.

After joining and bonding via TLPS, the alloy layer 424 solidifies into a solid alloy layer and may form metallurgic bonds with first parent layer 422 via the first rough surface 432 and the second parent layer 426 via the second rough surface 434. Joining and bonding via TLPS allows the GaSn alloy of the alloy layer 424 to inter-diffuse between the protrusions and indentations of the first rough surface 432 and the second rough surface 434 and inter-diffuse into the first parent layer 422 and the second parent layer 426.

Turning to FIG. 5, it shows a seventh schematic 500 of a sixth joint assembly 512. The sixth joint assembly 512 is a fifth configuration of a joint assembly of the present disclosure.

The sixth joint assembly 512 is similar to the first joint assembly 112 of FIGS. 1A-1B, comprising the joint section 120 and the second parent layer 126. However, the sixth joint assembly 512 includes a third parent layer 520 in place of the first parent layer 122. The joint section 120 may be sandwiched between, and may physically and thermally couple the third parent layer 520 to the second parent layer 126. The sixth joint assembly 512 may include the joint section 120 and comprise the solid alloy layer 164. The solid alloy layer 164 metallurgically bonded to the second parent layer 126 and the third parent layer 520.

The third parent layer 520 may be comprised of a different material, such as a different metal or a different metal alloy, from the second parent layer 126. The third parent layer 520 may comprise a core 522 that is coated with a plating 532. The plating 532 may be a metal, a metal alloy, or a metalloid that is thermally conductive. The plating 532 is a different material from the core 522. The plating 532 may comprise Ni or a Ni alloy. When joined and bonded via TLPS, the filler metal alloy of the solid alloy layer 164 may metallurgically bond to the plating 532.

The core 522 may comprise a material, such as a metal or a metal alloy, that may be unable to form metallurgic bonds with the filler metal alloy of the solid alloy layer 164. Alternatively, the core 522 may be a material, such as a metal or a metal alloy, that may form metallurgic bonds with the filler metal alloy of the solid alloy layer 164, but may react with at least a metal of the filler metal alloy to create amalgams and other defects comprised of another alloy than the GaSn alloy. The another alloy may comprise at least an element of metal from the core 522 and an element of metal from the filler metal alloy. For example, the core 522 may comprise aluminum (Al) that may form a metallurgic bond when joined and bonded with filler metal alloy of the solid alloy layer 164. However, when joined and bonded, the filler metal alloy may react with the Al to form amalgams of AlGa metal alloys. The amalgams may increase the brittleness of a metallurgic joint formed by the solid alloy layer 164 after solidification. Further, the amalgams may decrease shear strength and other mechanical properties of the metallurgic joint formed by the alloy layer after solidification. The plating 532 may prevent the surface sharing contact and therefore the formation of metallurgic bonds between the solid alloy layer 164 and the core 522 while joining thereto via a joint comprising one or more GaSn alloy layers. Upon solidification, joining, and bonding via TLPS, the first joint section 120 may therein be metallurgic joint section.

It is to be appreciated, that the metallurgic bonding of the solid alloy layer 164 to second parent layer 126 and the third parent layer 520 may be non-limiting, and other alloy layers of the present disclosure may metallurgically bond to the second parent layer 126 to the third parent layer 520 via TLPS. For example, the joint section 120 may comprise the alloy layer 324 embedded with the metal particles 326 of FIG. 3A. The alloy layer 324 may metallurgically bond the second parent layer 126 and the third parent layer 520, with metallurgic bonding between the alloy layer 324 and the plating 532, after being joined and bonded via TLPS.

It is to be appreciated, that physically and thermally coupling of the third parent layer 520 to the second parent layer 126 via the joint section 120 may be non-limiting, and other joint sections of the present disclosure may physically and thermally couple the third parent layer 520 to the second parent layer 126. For another example, the second joint section 220 of FIG. 2 or FIG. 3B may physically and thermally couple the third parent layer 520 to the second parent layer 126 after joining and bonding via TLPS. The first alloy layer 222 of FIG. 2 or the first alloy layer 372 of FIG. 3B may metallurgically bond to the third parent layer 520 via the plating 532. The third alloy layer 226 of FIG. 2 or the third alloy layer 376 of FIG. 3B may metallurgically bond to the second parent layer 126. Upon solidification, joining, and bonding via TLPS, the second joint section 220 may therein be metallurgic joint section.

Thus, disclosed herein is a plurality of configurations joint assemblies of the present disclosure joined and bonded via TLPS techniques to thermally couple two parent layers of material via a metallurgic bond and a joint section. The joint section metallurgically bonds to surfaces of each of the two parent layers physically coupling and thermally coupling the two parent layers. The surfaces of the parent layer that are metallurgically bonded to the joint section may be rough or smooth. A parent layer may be a feature of an electronic component and another parent layer may be a feature of a cooler, such as a heat exchanger. The parent layers may be metal or a metal alloy. For a first example, both parent layers may comprise the same metal or metal alloy, such as Cu. For a second example, both parent layers may be of different materials. One or more of the parent layers may be plated with a metal or alloy for metallurgic bonding with the joint section, such as a parent layer comprising a core of aluminum plated with Ni. The joint may comprise one or more layers of a filler metal alloy, where the filler metal alloy may be applied as a liquid and may be joined and bonded into a solid joint via the TLPS techniques. The filler metal alloy is a GaSn alloy of weight percent of Sn ranging from 4 wt. % to 24 wt. % and a weight percent of Ga of ranging from 90 wt. % to 76 wt. %. The weight percent of Sn in the alloy may be a smaller range, such as a wt. % of Sn ranging from 10 wt. % to 14 wt. %. Further, the weight percent of Sn in the alloy may be another smaller range, such as a wt. % of Sn ranging from 4 wt. % up to 10 wt. %. Additionally, the weight percent of Ga may be a smaller range, ranging from 90 wt. % to 86 wt. %. When solidified the joint formed via the filler metal alloy may have a weight of percent of Sn up to 10 wt. %, a weight percent of Ga ranging from 20 wt. % to 50 wt. % and a weight percent of Cu ranging from 50 wt. % to 80 wt. %.

Additionally, the filler metal alloy may have Cu particles or other solid metal particles as an additive. For an example, a liquid metal alloy with Cu particles may Sn up to 10 wt. %, a weight percent of Ga ranging from 20 wt. % to 50 wt. % and a weight percent of Cu ranging from 50 wt. % to 80 wt. %. An example configuration of the joint section may comprise only a layer of filler metal alloy. Another example configuration of the joint section may comprise a plurality of first layers of filler metal alloy and second layers of metallic foil, the second layers are sandwiched and interleaved between the first layers.

A set of reference axes 601 are provided for comparison between views shown in FIGS. 6-7. The reference axes 601 indicate a y-axis, an x-axis, and a z-axis. In one example, the z-axis may be parallel with a direction of gravity and the x-y plane may be parallel with a horizontal plane that a heat exchanger electronic assembly 602 may rest upon. When referencing direction, positive may refer to in the direction of the arrow of the y-axis, x-axis, and z-axis and negative may refer to in the opposite direction of the arrow of the y-axis, x-axis, and z-axis. A filled circle may represent an arrow and axis facing toward, or positive to, a view. An unfilled circle may represent an arrow and an axis facing away, or negative to, a view.

Turning to FIG. 6, it shows a schematic 600 of the heat exchanger electronic assembly 602. The schematic 600 is a cross-section or sectional schematic, showing the heat exchanger electronic assembly 602 when sectioned. The heat exchanger electronic assembly 602 is centered along a longitudinal axis 604. For this example, the longitudinal axis 604 is approximately parallel with the y-axis of the reference axes 601. The heat exchanger electronic assembly 602 may rest on a surface, such as a surface parallel with a plane formed between the x-axis and y-axis of the reference axes 601.

The heat exchanger electronic assembly 602 comprises at least an electronic component and a cooler. The electronic component or plurality of electronic components may be physically and thermally coupled to the cooler via a metallurgic bond, such as one or more of the TLPS joint configurations of the present disclosure. For example, the cooler may be a heat exchanger 620 and the electronic component may be an electronic component of a plurality of electronic components 622. The heat exchanger 620 may be the cooler for one or more of a plurality of electronic components 622 physically and thermally coupled therein. Said in another way, the heat exchanger electronic assembly 602 may comprise one or more of the electronic components 622 and the heat exchanger 620, where the electronic components 622 are physically and thermally coupled to the heat exchanger 620. For example, the one or more electronic components 622 are affixed to physically and thermally couple the heat exchanger via metallurgic bonds via a plurality of joint sections 624. Said in another way, each of the electronic components 622 are joined and bonded to the heat exchanger 620 via at least a joint section of the joint sections 624. Each of the joint sections 624 may be the first joint assembly 112 of FIGS. 1A-1B, the second joint assembly 212 of FIG. 2, the third joint assembly 312 of FIG. 3A, the fourth joint assembly 362 of FIG. 3B, the fifth joint assembly 412 of FIG. 4, and/or the sixth joint assembly 512 of FIG. 5.

The cooler of the heat exchanger electronic assembly 602, such as the heat exchanger 620, may be a cooler other than a forged pin cooler. Each of the one or more of the electronic components 622 may be a power electronic component or may be a component therein, such an inverter. For example, one or more of the electronic components 622 may be or may be a portion of a motor control unit (MCU) that is integrated with an inverter, such as an EV traction inverter. Additionally or alternatively, each of electronic components 622 may be communicatively and electrically coupled to other electronic components, such as other electronic power component, and each of the electronic components 622 may physically and thermally couple the other electronic components to the heat exchanger 620. Additionally or alternatively, each of the electronic components 622 may be an assembly of smaller electronic components that may be referred to as an electronic assembly.

Each of the joint sections 624 may be joined to the heat exchanger 620 at a first parent surface 626, where the first parent surface 626 comprises a material that is compatible with joining and bonding to the joint sections 624. The first parent surface 626 may be a surface of a parent layer compatible with bonding to the joint sections 624 via TLPS, such as the first parent layer 122 or second parent layer 126 of FIGS. 1A-3B, the first parent layer 422 or second parent layer 426 of FIG. 4, or the third parent layer 520 of FIG. 5. One or more of joint sections 624 may be sandwiched between each of the electronic components 622 and the first parent surface 626. The electronic components 622 may be physically and thermally coupled via the TLPS joint to the first parent surface 626. For example, the first parent surface 626 may be smooth. For another example, the first parent surface 626 may be a rough surface. When rough, the first parent surface 626 may be the first rough surface 432 or the second rough surface 434 of FIG. 4. The first parent surface 626 may be arranged horizontal, such as to be normal relative to a vertical axis, such as the z-axis of the reference axes 601. The first parent surface 626 may be a top facing surface.

The heat exchanger 620 may comprise a metal with a high thermal conductivity, such as a Cu or Aluminum. The high thermal conductivity of the heat exchanger 620 may conduct thermal energy from metallurgically bonded components and physically coupled components at greater rates compared to materials of lower thermal conductivity.

Before joining and bonding via TLPS, GaSn alloy of each the joint sections 624 may coat a first area of the first parent surface 626. After joining and boding via TLPS, approximately all of the first area of the first parent surface 626 may be joined and bonded via a metallurgic bond to a joint section of the joint sections 624 formed therein. The first area may be greater than or equal to an area of 30 mm×30 mm. Said in another way, each of the joint sections 624 may have a cross-sectional area greater than or equal to 30 mm×30 mm, and each of the joint sections 624 may join and bond via a metallurgic bond to the first area of the first parent surface 626, where the first area is greater than or equal to 30 mm×30 mm. Additionally, before joining and bonding via TLPS, GaSn alloy of each the joint sections 624 may coat a second area of a second parent surface of the electronic components 622, where the second area is greater than or equal to 30 mm×30 mm. After joining and bonding via TLPS, approximately all of the surface of the second areas of the second parent surfaces of the electronic components 622 may be joined and bonded via a metallurgic bond to the joint sections 624. Said in another way, each of the joint sections 624 may join and bond via a metallurgic bond to the second area of a second parent surface of an electronic component of the electronic components 622, where the second areas are greater than or equal to 30 mm×30 mm. The bond line thickness of the joint sections 624 may be between 150 and 250 microns in thickness. It should be appreciated, that the sizing of the first area and the second area of the joints may be non-limiting, and the GaSn alloy may cover, join, and bond to areas that are smaller than 30 mm×30 mm.

The heat exchanger 620 may comprise a cooling channel 632. The cooling channel 632 may house and allow fluid flow of heat transfer fluid 634. The heat transfer fluid 634 may be a coolant. As a coolant, the heat transfer fluid 634 may enter the cooling channel 632 at a lower temperature than the heat exchanger 620 and may remove thermal energy from the heat exchanger 620. The heat transfer fluid 634 may be oil. However, it is to be appreciated that the heat transfer fluid 634 may be another heat exchange fluid. The heat transfer fluid 634 may enter the cooling channel 632 via an inlet 642 and may exit the cooling channel 632 via an outlet 644. An inflow of heat transfer fluid 634 to and through the inlet 642 into the cooling channel 632 may be represented via arrows 652. An outflow of heat transfer fluid 634 through and from the inlet 642 out from the cooling channel 632 may be represented via the arrows 654.

The inlet 642 may be a port, e.g., an inlet port. The inlet 642 may fluidly couple and seal with a fluid source, such as a hose, a pipe, a fluid passage, or another type of fluid line. Additionally or alternatively, the inlet 642 may fluidly couple and seal with another fluid port or another outlet of an adjoining heat exchanger, where the adjoining heat exchanger is separate from the heat exchanger 620. The inflow to the inlet 642 may be driven via having a first pressure for a first volume in fluid communication with the inlet 642 that is greater and more positive compared to a second pressure of the cooling channel 632. For example, the inlet 642 may downstream of a pressure side (e.g., exhaust side) of a pump. Likewise, the outlet 644, may be a port, e.g., an outlet port. The outlet 644 may fluidly couple and fluidly seal with a fluid line, such as a hose, a pipe, a fluid passage, or another type of fluid line. Additionally or alternatively, the inlet 642 may fluidly couple and seal with another fluid port or another inlet of the adjoining heat exchanger previously mentioned or another adjoining heat exchanger. The outflow from the outlet 644 may be may be driven via having a third pressure for a second volume in fluid communication with the inlet 642 that is smaller and more negative compared to the second pressure of the cooling channel 632. For example, the outlet 644 may be upstream of a suction side of a pump. It is to be appreciate that the number of inlets and outlets may be non-limiting, and there may be a plurality of inlets and/or outlets to the cooling channel 632, where the plurality of inlets and outlet share the same function as and that may include the inlet 642 and the outlet 644, respectively.

Waste heat and other thermal energy generated via the electronic components 622 may be removed via conduction and the joint sections 624. The joint sections 624 may conduct thermal energy away from the electronic components 622 joined, metallurgically bonded to, and physically coupled to therein. Each of the joint sections 624 joined to an electronic component of the electronic components 622 conducts thermal energy away from the joined power electronic component. Thermal energy may be conducted away from the joint sections 624 into the heat exchanger 620, such as at the first parent surface 626. The surfaces of the cooling channel 632 are cooled by the heat transfer fluid 634 and may conduct thermal energy out of the material of the heat exchanger 620. Thermal energy may be transferred from the surfaces of the cooling channel 632 to the heat transfer fluid 634 via conduction and convection. The thermal energy may be removed from the cooling channel 632 and the heat exchanger 620 via flowing the heat transfer fluid 634 through the outlet 644 after the heat transfer fluid 634 is heated via conduction and convection. Heat transfer fluid 634 may be replenished to the cooling channel via an inflow of heat transfer fluid 634 through the inlet 642. The inflow of heat transfer fluid 634 represented via arrows 652 may have lower temperature and a lower thermal energy compared to the outflow of heat transfer fluid 634 represented by arrows 654.

Before joining or bonding via TLPS, each of the joint sections 624 and each of the electronic components 622 may be fixed to the heat exchanger 620 via a fixture assembly. The fixture assembly may prevent movement of the joint sections 624 and electronic components 622, unless there is a deliberate force greater than a threshold of force to unfix the heat exchanger electronic assembly 602 therein. For example, the fixture assembly may clamp the electronic components 622 to the heat exchanger 620. The electronic components 622 to the heat exchanger 620 may be clamped via fixture assembly before, during, and after the solidification of the joint sections 624 via TLPS. Said in another way the fixture assembly may clamp the heat exchanger electronic assembly 602 before, during, and after the joining, bonding, and physically coupling of the electronic components 622 to the heat exchanger 620 via the joint sections 624 through TLPS. The fixture may be placed an oven or a furnace, such as a positive pressure oven or a positive pressure furnace, while clamping the electronic components 622 and the joint sections 624 to the heat exchanger 620. The oven or furnace may join, bond, and solidify the GaSn alloy of the joint sections 624 to the electronic components 622 and the heat exchanger 620 during a TLPS method. Said in another way, the oven or furnace may join and bond the electronic components 622 to the heat exchanger 620 via the joint sections 624 and TLPS.

Turning to FIG. 7, it shows a schematic 700 of an electronic component 622a joined and bonded to the first parent surface 626. The electronic component 622a may be one of the electronic components 622 of FIG. 6.

The electronic component 622a may be a power electronic component comprising a plurality of semi-conductor chips 722 and a substrate section 720, where the semi-conductor chips 722 are physically coupled and electrically coupled to the substrate section 720 via a first substrate layer 732. The first substrate layer 732 may be a circuit board or a similar component for physically coupling, electrically coupling, and communicatively coupling the semi-conductor chips 722 and other electronic elements and components to the first substrate layer 732, therein. The substrate section 720 may also include a second substrate layer 734 and a third substrate layer 736. The second substrate layer 734 is an intermediate layer of material sandwiched between the first substrate layer 732 and the third substrate layer 736. The third substrate layer 736 may be a layer comprised of a material joinable and bondable via TLPS to at least a joint section 624a. The joint section 624a may be a joint section of the joint sections 624 of FIG. 6. The third substrate layer 736 may be a layer compatible with bonding to the joint section 624a via TLPS, such as the first parent layer 122 or the second parent layer 126 of FIGS. 1A-3B, the first parent layer 422 or second parent layer 426 of FIG. 4, or the third parent layer 520 of FIG. 5. For example, the third substrate layer 736 may be or have a surface that comprises Cu or may be plated with Cu or Ni. The joint section 624a may be sandwiched between the third substrate layer 736 and the heat exchanger 620.

The joint section 624a may join, bond, and physically couple the third substrate layer 736 to the heat exchanger 620, such as via joining and bonding via TLPS. More specifically, the joint section 624a may form a metallurgic bond with and between a second parent surface 742 and the first parent surface 626, physically coupling and thermally coupling the second parent surface 742 to the first parent surface 626. The second parent surface 742 is a surface of the third substrate layer 736 that may comprise a material compatible with metallurgic bonding and joining to the joint section 624a via TLPS. For example, the second parent surface 742 may comprise Cu or Ni.

For example, the second parent surface 742 may be smooth. For another example, the second parent surface 742 may be a rough surface. When rough, the second parent surface 742 may be the first rough surface 432 or the second rough surface 434 of FIG. 4. The second parent surface 742 may be arranged horizontal, such as to be normal relative to a vertical axis such as the z-axis of the reference axes 601. For example, the second parent surface 742 may be a top facing surface.

Before joining and bonding via TLPS, GaSn alloy of the joint section 624a may coat an area of the second parent surface 742. The area of the second parent surface 742 may be equal to or greater than 30 mm×30 mm. After joining and bonding via TLPS, approximately all of the area of the second parent surface 742 may be joined and bonded via a metallurgic bond to the joint section 624a formed therein. For example, of an area that is greater than or equal to 30 mm×30 mm may be joined and bonded via a metallurgic bond to the joint section. Said in another way, the joint section 624a may have a cross-sectional area greater than or equal to 30 mm×30 mm, and the joint section 624a may join and bond via a metallurgic bond to an area of the second parent surface 742 greater than or equal to 30 mm×30 mm. However, it should be appreciated that the sizing of the area of the second parent surface 742 joined and bonded to the joints may be non-limiting, and the GaSn alloy may cover, join, and bond to areas that are smaller than 30 mm×30 mm.

Before joining via TLPS, one or more layers of GaSn alloy of the joint section 624a may be surrounded by a plurality of sealing features 752. More specifically, the sealing features 752 may surround an area such as a first area of the first parent surface 626 and/or a second area of the second parent surface 742 joined and bonded to the joint section 624a. The sealing features 752 may define the shape and perimeter of the first area and/or second area. The sealing features may physically couple to the first parent surface 626 and/or the second parent surface 742. For an example, the sealing features 752 may prevent liquid metal alloy (e.g., the GaSn alloy in a liquid phase before TLPS) of the joint section 624a from spreading outward from and crossing the perimeter of the first area, such as when physically coupled to the first parent surface 626. For another example, the sealing features 752 may prevent liquid metal alloy of the joint section 624a from spreading outward from and crossing the perimeter of the second area, such as when physically coupled to the second parent surface 742.

The sealing features 752 may be removed after the joint section 624a is joined and bonded via to the first area of the first parent surface 626 and the second area of the second parent surface 742. For example, the sealing features 752 are removed from the schematic 700 and the heat exchanger electronic assembly 602 after the joint section 624a is joined and bonded to the first and second parent surfaces 626, 742 via TLPS. It is to be appreciated, the sealing features 752 may be removed before the joint section 624a is joined and bonded via to the first area of the first parent surface 626 and the second area of the second parent surface 742. For another example, the sealing features 752 may be removed from the schematic 700 and the heat exchanger electronic assembly 602 before the joint section 624a is joined and bonded to the first and second parent surfaces 626, 742 via TLPS. It is to be appreciated that the sealing features 752 may be used for other joint sections comprising liquid GaSn alloy of the present disclosure before bonding, joining, and solidifying via TLPS. For example, the sealing features 752 may be used in the same purpose described above for the other joint sections of joint sections 624 attached to other parent surfaces of other electronic components of electronic components 622.

For an example, the sealing features 752 may be a plurality of adhesive barriers, such as strips of tape, that may be physically coupled to a parent surface and surround the perimeter of an area of a parent surface. A coating GaSn alloy of a joint section of joint sections 624 may be applied to the area, and therein joined and bonded to the area via TLPS. However, it is to be appreciated that the sealing features 752 may be non-limiting and may be of other configurations, including a singular component. For another example, the sealing features 752 may be a mold that is a unitary body with an opening premade into the shape of an area of a parent surface. The mold may surround the area, and more specifically the opening may surround the perimeter of the area. Coating of GaSn alloy of a joint section of the joint sections 624 may be applied to the area, and therein joined and bonded to the area via TLPS.

Thus, disclosed herein is a configuration of a cooler electronic assembly, wherein the electronics components may be thermally coupled and physically coupled via a metallurgic bond using TLPS techniques. The direct bonding provided by the method may increase the rate of heat exchange between the heat exchanger and electrical components. Additionally, the configuration may be manufactured without causing degradation to the electronic component or heat exchanger by keeping temperature below a first threshold of 250° C. and pressures below a second threshold of 20 MPa while joining and bonding. The increased tensile strength and compressive strength of the joint may increase the lifespan of the components of the heat exchanger electronic assembly.

The cooler electronic assembly comprises at least an electronic component and a cooler physically coupled and thermally coupled via a metallurgic bond of a configuration of a joint section of the present disclosure to parent surfaces of the electronic component and the cooler. The joint section is metallurgically bonded to the electronic component and the cooler via a TLPS method. The electronic component may be power electronic component such as a EV inverter or a component of an EV inverter. The electronic component may be an assembly of smaller electronics and smaller electronic components. There may be a plurality of electronic components each physically coupled and thermally coupled via a joint section to the cooler. The cooler may be a heat exchanger. A coating of filler metal alloy of the present disclosure may be applied as a liquid to a surface of each parent layer of the electronic component and the cooler. The electronic component and cooler may be fixed via a fixture assembly, where a joint assembly may be formed between the electronic component and cooler before joining and bonding via TLPS. The fixture assembly may be joined and bonded with the electronic component and the cooler. The coatings of liquid filler metal alloy applied to the electronic component, the cooler, and the joint section may have areas comprising a length greater than 30 mm and a width greater than 30 mm. However, it should be appreciated that dimensions of an area coatings of liquid filler metal alloy are applied to may be non-limiting, and the areas may be less than 30 mm in length and/or a width less than 30 mm.

Turning to FIG. 8, it shows a flowchart of a first method 800 used to manufacture and assemble one or more electrical components to a heat exchanger via a TLPS joining and bonding technique. The first method 800 begins at 802, where an alloy of Ga and Sn is prepared for use in TLPS in the first method 800. The GaSn alloy is prepared via being melted together and maintained in a liquid state before application for joining the heat exchanger and one or more substrates of an electronic component. Once prepared, the GaSn alloy is liquid at room temperature. The GaSn alloy may be prepared in larger quantities with at a greater efficiency, where less energy is consumed via melting or other forms liquefying the GaSn alloy, compared to silver sintering materials and similar sintering materials produced via batch methods.

For an example, the GaSn alloy in liquid form prepared to have a wt. % of Sn ranging 10 wt. %-24 wt. %. The liquid GaSn alloy has wt. % of Ga ranging from 90 wt. %-76 wt. %. For this or another an example of a configuration, the liquid GaSn alloy has a wt. % of Sn along a first range from 10 wt. %-14 wt. %. Likewise, the liquid GaSn alloy has a wt. % of Ga along a second range from 90 wt. %-86 wt. %

For another example, the GaSn alloy are prepared by having solid metal particles such as Cu particles, interspersed in the liquid GaSn alloy. The metal particles may be the metal particles 326 of FIGS. 3A-3B. After interspersion of the metal particles, the weight percent of the metal may be along a first range of 50 wt. %-80 wt. % of the liquid alloy, where the metal may be Cu. The weight percent of Sn may be up to 10 wt. % of the liquid alloy after dispersion of the metal particles. The weight percent of Ga may be 20 wt. %-50 wt. % of the liquid alloy after dispersion of the metal particles.

At 804 the heat exchanger and/one or more electronic components are prepared for joining via TLPS. The heat exchanger has been assembled and is brought into a position for the joint to be joined and bonded via the GaSn alloy. Likewise, the electronic components brought into a position for the joining and bonding steps of the first method 800. The heat exchanger is fixed to a position to apply a coating of an alloy for joining and bonding. Likewise, the one or more electronic components are fixed to positions to be prepared for joining and bonding. The fixed positions of the heat exchanger and the electronic components may allow for a coating of the alloy for joining and bonding to be applied to substrates thereto. A coating of GaSn liquid alloy may be applied to at least a substrate of the heat exchanger or the one or more electronic components in steps after 804 of the first method 800. Alternatively, a coating of GaSn liquid alloy may be applied to substrates of both the heat exchanger and the one or more electronic components in steps after 804 of the first method 800. For example, the heat exchanger may be fixed to a station. For another example, the heat exchanger may be fixed via a fixture assembly. More specifically, the heat exchanger may be fixed to a fixture plate of a fixture assembly. The one or more electronic components may be fixed in a position a component of a fixture assembly, such as a fixture plate. 804, may include optional steps at both 806, 808.

At 806 an area of a surface of the heat exchanger may be marked and prepared for joining and bonding with the GaSn alloy. The area referred to herein as a first joining area. A surface of the heat exchanger may be marked with a perimeter for the first joining area. For example, the first joining area may be cleaned to prevent impurities from being joined and bonded. Additionally, the first joining area may be wrapped with one or more sealing features to prevent GaSn alloy applied from spreading outside the perimeter of the first joining area. For an example, the one or more sealing features may be the one or more sealing features 752 from FIG. 7.

Additionally, at 808 another area of a surface of an electronic component is marked and prepared for joining and bonding with the GaSn alloy via TLPS. The other area may be referred to herein as a second joining area. The second joining area of 808 is marked on substrate of the electronic component that is to face and bond to the heat exchanger when the electronic component is joined to the heat exchanger. A surface of the electronic component, such as the second parent surface 842 of the substrate section 720 of FIG. 7, may be marked with a perimeter for the second joining area. For example, the second joining area may be cleaned to prevent impurities from being joined into the joint via TLPS. The second joining area may be wrapped with one or more sealing features to prevent GaSn alloy applied from spreading outside the perimeter of the second joining area.

It is to be appreciated, that there may be a plurality of first joining areas and a plurality of surfaces for the first joining areas, with the heat exchanger having one or more first joining areas for each electronic component to be joined and bonded to the heat exchanger via TLPS. The number of first joining areas may be dependent on the number of electronic components that are desired for joining to the heat exchanger, wherein there is at least a first joining area for each electronic component that is desired for joining to the heat exchanger. Likewise, there may be a plurality of second joining areas. There may be at least a second joining area specific to each electronic component that is desired for joining to the heat exchanger.

The joining areas at 806 and 808 may be marked via an outline, such as a marking made via a print or through the application of a pigment around the perimeter of each joining area. The GaSn may be applied and joined to approximately the within the perimeter of the marking.

After 804, the first method 800 continues 822. At 822, the GaSn alloy is applied as a coat to the joining surfaces. 822 is comprised of one or more sub-steps.

822 includes a sub-step at 824, where the GaSn alloy is applied as a first coating to the joining surface of the heat exchanger. The first coating is applied to one or more of plurality of areas, such as the one or more first joining areas described for 806. The first coating of GaSn alloy applied to heat exchanger may be referred to herein as a first GaSn alloy coating. The GaSn alloy is applied to surfaces that are part of a metal terminations of the heat exchanger. For a first configuration the surfaces and the metal terminations are comprised of Cu. However, it is to be appreciated for alternative configurations, the surfaces and metal terminations may be comprised of one or more other metals and/or one or more alloys comprising other metals, such as Ni. The joining areas are marked at surfaces of the metal terminations or substrates of the electronic component and the heat exchanger.

822 includes a sub-step at 826, where GaSn alloy is applied as a second coating on a surface of a substrate of one or more electronic components. The second coating is applied to an area of the substrate of each of the electronic components, such as one or more of the second joining areas. The substrate of each of the electronic components may be a metal termination. The GaSn alloy applied to the substrate of an electronic component may be referred to as a second GaSn alloy coating. For a first configuration, the surface of the substrate of the electronic component are comprised of Cu. However, it is to be appreciated for alternative configurations, the surface may comprise one or more metals and/or one or more alloys comprising other metals, such as Ni.

It is to be appreciated, that at least one of the sub-steps at 824 or 826 may be performed by the method. If no GaSn alloy in a liquid form is applied to one or more surfaces of the heat exchanger at 824, then at 826 the first method 800 applies GaSn in a liquid form to one or more surfaces of one or more electronic components. Likewise, if no GaSn alloy in a liquid form is applied to one or more surfaces of the electronic components at 826, then at 824 the first method 800 applies GaSn in a liquid form to one or more surfaces of the heat exchanger.

The first method 800 continues to 832, where the one or more electronic components are fixed to the heat exchanger. Each of the electronic components is fixed such as to be prevented from moving separately from the heat exchanger and to be in contact with a first GaSn alloy coating of the heat exchanger. The one or more electronic components may be fixed to the heat exchanger via clamping, such as via a fixture assembly. The first GaSn alloy coating and/or a second GaSn alloy coating of the substrate of the electronic component are sandwiched between the surface of the heat exchanger and the substrate. The heat exchanger and the electronic component are fixed in relative positions such that the first joining area of the heat exchanger aligns with the second joining area of the electronic component. When aligned, first joining area may superimpose with or be within a volumetric projection of the second joining area, or vice versa. When fixed, the second joining area of the electronic component is aligned with the first joining on the surface of the heat exchanger, and GaSn alloy connects the heat exchanger and the substrate of the electronic component. At least the first GaSn alloy may contact the second joining area to form a single layer of GaSn alloy sandwiched between the parent layers of the heat exchanger and the electronic component. Likewise, the first GaSn alloy coating of the heat exchanger may merge with the second GaSn alloy coating attached to the substrate of the electronic component, with the second GaSn alloy coating contacting the second joining area. When merged, the first and second GaSn alloy coatings are combined into a single layer of GaSn alloy sandwiched between the parent layers of the heat exchanger and the electronic component.

The first method 800 continues to 842 where the GaSn alloy coating is joined and solidified into a GaSn alloy joint, joining the parent layers of the electronic component and the heat exchanger. 842 is comprised of a plurality of sub steps. Starting at 844, joining begins by placing the assembly of the heat exchanger and the one or more electronic components in a chamber of a heating device. The heating device may be an oven or a furnace, such as a positive pressure oven or a positive pressure furnace. Additionally or alternatively, the heating device may be sealed from the surrounding atmosphere (e.g., air tight), such as an air tight oven or an air tight furnace. The heat exchanger and one or more electronic components may be inserted and joined in the chamber with the fixture assembly. The heating device apply thermal energy to join and bond the GaSn alloy coating via TLPS. At 846 the chamber of the heating device housing the assembly of the heat exchanger and the one or more electronic components is brought to a joining temperature, where solidification, joining and bonding GaSn alloy to a parent surface via TLPS may occur. The chamber has an atmosphere of inert gas, such as N2. The joining temperature is isothermal. Said in another way, the joining and bonding temperature may be a constant temperature, where the joining and bonding temperature stays approximately the same during the joining and bonding method of TLPS. The joining temperature may be at temperatures of a temperature range at or between 150° C. and 250° C. For a first example, the joining temperature is desired to be at temperature within a smaller range at or between temperatures of 150° C. and 200° C. After the temperature is increase to the joining temperature, the first method 800 continues to 848, where the assembly of the heat exchanger and the one or more electronic components are joined via TLPS for a non-zero duration of time, referred to herein as a sinter time. During joining and bonding the coating sandwiched between each electronic component and the heat exchanger is joined and bonded via TLPS into a GaSn alloy joint. The sinter time may be less than 4 hrs. For a first set of examples, the sinter time is desired to be between a range of 0.5 hrs (30 minutes) and 2 hrs. For an example, the first and/or second joining areas may be surrounded by sealing features during the joining and bonding the GaSn alloy joint via TLPS. The sealing features may therein remain coupled to the heat exchanger and/or electronic components during joining and bonding the GaSn alloy joint via TLPS. For another example, the sealing features may be removed from the heat exchanger and/or one or more electronic components before joining and bonding the GaSn alloy joint via TLPS.

After forming a solid joint via joining and bonding using TLPS, a weight percent of the Cu particles may be at or between 50 wt. %-80 wt. % of the solid alloy layer. Likewise, after forming the solid joint, a weight percent of Sn may be up to 10 wt. % of the solid alloy layer. Further after forming the solid joint, a weight percent of Ga may be at or between 20 wt. %-50 wt. % of the solid alloy layer.

After joining and bonding, and solidification of the joint, 842 ends. After 842, the first method 800 ends.

Turning to FIG. 9, it shows a flowchart of a second method 900 used to manufacture and assemble one or more electrical components to a heat exchanger via a TLPS joining and bonding technique. The second method 900 includes identical steps to the first method 800 of FIG. 8. Steps introduced in the first method 800 may not be reintroduced for brevity.

The second method 900 is the same as the first method 800 with exception to 822, which includes a plurality of additional sub steps. After the first coating is applied to the heat exchanger at 824, the second method 900 continues to 922. At 922 a layer of metallic foil is fixed atop a layer of GaSn alloy coating. The GaSn alloy coating at 922 is a previous coating of GaSn alloy that has been applied. For example, the GaSn alloy coating may be a first GaSn alloy coating applied to a surface of the heat exchanger. The metallic foil may be a Cu foil such as a metallic foil layer from the second joint assembly 212 of FIG. 2 or the fourth joint assembly 362 of FIG. 3B. For an example, the Cu foil may between 0.0005″ (inches) and 0.002″ (inches) in thickness. After 922, the second method 900 continues to 924, where another coating is applied atop the metallic foil. Each GaSn alloy coating applied and sandwiched between layers of metallic foil becomes a layer of filler metal alloy, such as the first alloy layer 222, the second alloy layer 224, or third alloy layer 226 of FIG. 2 or the first alloy layer 372, the second alloy layer 374, or the third alloy layer 376 of FIG. 3B. Each metallic foil applied atop a coating of GaSn alloy becomes a solid metallic layer such as the first foil layer 232 or second foil layer 234 of FIG. 2 and FIG. 3B.

922 and 924 are part of loop 928. After applying the coating of GaSn alloy at 924, the second method 900 continues to 930, where the second method 900 determines if the desired amount of layers of metallic foil and GaSn alloy coating have been added to be sandwiched between the heat exchanger and the electronic component. If layers of metallic foil and GaSn are not equal to the desired amount of layers of each (e.g., 930 is NO), the second method 900 returns to 922, where another layer of foil is applied and fixed to the previous coating of the GaSn layer. If layers of metallic foil and GaSn are equal to the desired amount of layers for each (e.g., 930 is YES), the second method 900 exits loop 928 and proceeds to 832.

After 842, the second method 900 ends.

It is to be appreciated that the second method 900 the steps of loop 928 may be altered if 808 were performed by the second method 900. For example, during the last cycle of loop 928, 930 may determine that a single and final cycle of loop 928 may add the desired amount of layers of metallic foil and GaSn alloy. For the final cycle of loop 928, 924 is not performed by the second method 900. A final coat of GaSn alloy to the final layer of metallic foil may be applied at 832 when fixing the electronic component to the heat exchanger assembly at relative positions. The final coat of GaSn alloy applied to the final layer of foil may be the second GaSn coating applied to the second joining area at 826. The final coat of GaSn alloy may be applied to and contacted by the final layer of foil when fixing the electronic component to the heat exchanger via a fixture assembly.

Thus, disclosed herein is a method to form a heat exchanger electronic assembly and a thermally conductive metallurgic joint, wherein the electronics components may be thermally coupled and physically coupled via a metallurgic bond using TLPS techniques to form and solidify the thermally conductive metallurgic joint. The direct bonding provided by the method may increase the rate of heat exchange between the heat exchanger and electrical components. Additionally, the method may allow for joining and bonding a filler metal alloy between two parent surfaces, while preventing degradation to the electronic component or heat exchanger each comprising the parent surfaces by keeping temperature below a first threshold of 250° C. and pressures below a second threshold of 20 MPa while joining and bonding. The increased tensile strength, compressive strength, and shear strength of the joint compared to other sintered and soldered joints may increase the lifespan of the components of the heat exchanger electronic assembly.

Turning now to FIG. 10, a vehicle 1000 is shown comprising a powertrain 1001 and a drivetrain 1003. The vehicle 1000 may have a front end 1002 and a rear end 1004, located on opposite sides of vehicle 1000. Objects, components, and features of the vehicle 1000 referred to as being located near the front may be closest to the front end 1002 compared to the rear end 1004. Objects, components, and features of the vehicle 1000 referred to as being located near the rear may be closest to the rear end 1004 compared to the front end 1002. The vehicle 1000 may have a longitudinal axis 1030. The powertrain 1001 and drivetrain 1003 may have a length parallel with the longitudinal axis 1030.

The powertrain 1001 comprises a prime mover 1006 and a transmission 1008. For an example, the prime mover 1006 may be an internal combustion engine (ICE). For another example, the prime mover 1006 may be an electric machine. The prime mover 1006 is operated to provide rotary power to the transmission 1008. The transmission 1008 receives the rotary power produced by the prime mover 1006 as an input and outputs rotary power to the drivetrain 1003 in accordance with a selected gear or setting.

The vehicle 1000 may be a commercial vehicle, light, medium, or heavy duty vehicle, a passenger vehicle, an off-highway vehicle, a commercial vehicle, agricultural vehicle, and/or sport utility vehicle. For an example embodiment, the vehicle 1000 may be a wheeled vehicle, such as an automobile. However, additionally or alternatively, the vehicle 1000 may be a plane, a boat, or other vehicle system. Additionally or alternatively, the vehicle 1000 and/or one or more of its components, such as components of the powertrain 1001 and/or the drivetrain 1003, may be used in industrial, locomotive, military, agricultural, and/or aerospace applications. In an example, the vehicle 1000 is an all-electric vehicle or a vehicle with all-electric modes of operation, such as a plug-in hybrid vehicle. As such, the prime mover 1006 may be an electric machine, such as an electric motor/generator. For an example, the vehicle 1000 may be a hybrid vehicle, wherein there are multiple torque inputs to the transmission 1008. As such, there may be at least another mover with an input to the transmission 1008 besides the prime mover 1006. If the prime mover is an ICE or another non-electric machine mover, the other mover may be an electric machine, such as an electric motor or an electric motor/generator. The vehicle 1000 may have a driveshaft 1022. The driveshaft 1022 may be rotatably coupled to the transmission 1008, such that the transmission 1008 may rotate and drive the driveshaft 1022.

The prime mover 1006 may be powered via energy from an energy storage device 1005. For example, the energy storage device 1005 is a battery, such as a traction battery, configured to store electrical energy. An inverter 1007 may be arranged between the energy storage device 1005 and the prime mover 1006 and configured to adjust direct current (DC) to alternating current (AC). The inverter 1007 may include a variety of components and circuitry with thermal demands that effect an efficiency of the inverter.

The drivetrain 1003 may include an axle assembly 1012. The axle assembly 1012 may be configured to drive a set of wheels 1014. In one example, the axle assembly 1012 is arranged near the rear of the vehicle 1000 and thereby comprises a rear axle. For another example, the axle assembly 1012 may be arranged near the rear of the vehicle 1000 and thereby comprise a front axle. For another example, there may be an additional axle assembly arranged near the front of the vehicle 1000 separate from the axle assembly 1012. The additional axle assembly may be drivingly coupled to the transmission such as to be driven by the transmission 1008 or another transmission. The vehicle 1000 may include additional wheels that are not coupled to the drivetrain 1003.

The transmission 1008 may drivingly couple to the axle assembly 1012 via the driveshaft 1022. Said in another way, the transmission 1008 may drivingly couple to the driveshaft 1022, such as to be driven via rotational energy, such as a torque, from the transmission 1008. Likewise, the driveshaft 1022 may drivingly couple the axle assembly 1012, such as to be driven via rotational energy from the driveshaft 1022. In some configurations, such as shown in FIG. 10, the drivetrain 1003 includes a transfer case 1010 configured to receive rotary power output by the transmission 1008. The driveshaft 1022 may drivingly couple to the transfer case 1010 and may be drivingly coupled to the transmission 1008 via the transfer case 1010.

The axle assembly 1012 may include a differential 1016 and a first set of axle shafts. The differential 1016 may drivingly couple the first set of axle shafts such as to transfer torque to and drive the first set of axle shafts. The differential 1016 may distribute unequal torque to one or more wheels of wheels 1014 drivingly coupled at opposite ends of the axle assembly 1012. The differential 1016 may therein distribute unequal torque to each wheel of the wheels 1014.

The vehicle 1000 includes cooling system for one or more power electronic components, such as a cooling circuit 1050. The cooling circuit 1050 may include a plurality of fluid lines 1062 that may transport cooling fluid, such as oil, to cool one or more components of the vehicle 1000. The cooling circuit 1050 may include an assembly 1052, a cooling unit 1058, and a pump 1060. The assembly 1052 is a heat exchanger electronic assembly, and comprises at least a heat exchanger 1054 and an electronic assembly 1056. The electronic assembly 1056 may be physically coupled to the heat exchanger 1054 via a joint comprised of an alloy of the present disclosure. The joint may be solidified between, and may be joined and metallic bonded to the heat exchanger 1054 and the electronic assembly 1056 via TLPS. However, the assembly 1052 may include one or more of a plurality of other heat exchangers each with an electronic assembly, where the other heat exchangers may be the same configuration as heat exchanger 1054. Likewise, there may be one or more of a plurality of other electronic components physically coupled to the heat exchanger 1054, where the other electronic components may be physically coupled via joining and bonding via a TLPS joint of the present disclosure. The assembly 1052 may be the heat exchanger electronic assembly 602 of FIG. 6. The heat exchanger 1054 and the electronic assembly 1056 may be the heat exchanger 620 and one or more of the electronic components 622, respectively.

The cooling unit 1058 may be a device to remove thermal energy from the cooling fluid of the cooling circuit 1050. For example, the cooling unit 1058 may be a chiller or a refrigeration unit. For another example, the cooling unit 1058 may be another heat exchanger, where fluid exiting the heat exchanger 1054 is received as a first flow of fluid to the cooling unit 1058, and the first flow of fluid is cooled by a second flow of fluid that enters the cooling unit 1058. The cooling unit 1058 may remove thermal energy from fluid flow out of the heat exchanger 1054, and in turn remove thermal energy from the electronic assembly 1056. The pump 1060 may increase pressure of fluid in the cooling circuit 1050, and more specifically regenerate pressure lost from the fluid moving across the heat exchanger 1054. For an example, the pump 1060 may increase the pressure of fluid downstream of the cooling unit 1058, and therein the pump 1060 may regenerate pressure lost from fluid moving across the cooling unit 1058. However, it is to be appreciated that the arrangement of cooling unit 1058 and the pump 1060 may be non-limiting. For another example, the pump 1060 may be upstream of the cooling unit 1058, and may be controlled to increase pressure to account for an estimated pressure loss of the cooling unit 1058. For these examples, the cooling unit 1058 and pump 1060 may decrease the temperature and increase the pressure, respectively, of the fluid in the cooling circuit 1050 to an inlet temperature and inlet pressure for the heat exchanger 1054.

The transmission 1008 may be a gearbox. Alternatively, the transmission 1008 may be an axle transmission or a trans axle transmission, and may be arranged or be part of an axle assembly such as the axle assembly 1012. In some embodiments, additionally or alternatively, the transmission 1008 may be a first transmission, and the vehicle 1000 may have a second transmission. The second transmission may be arranged nearer to the rear side or in another position of the vehicle 1000 compared to transmission 1008.

The drivetrain 1003 is shown in a rear-wheel drive configuration, although other configurations are possible. For one or more examples, the drivetrain 1003 may include a front-wheel drive, a four-wheel drive configuration, or an all-wheel drive configuration. Further, the drivetrain 1003 may include one or more tandem axle assemblies. For example, there may be one or more axle assemblies in addition to axle assembly 1012, and there may be one or more axles in addition to the axle of axle assembly 1012. As such, the drivetrain 1003 may have other configurations without departing from the scope of this disclosure, and the configuration shown in FIG. 10 is provided for illustration, not limitation. For example, in some embodiments, additionally or alternatively, the transmission 1008 may be a first transmission, and the vehicle 1000 may have a second transmission arranged on the second set of axle shafts. The transmission 1008 may be a gearbox. Alternatively, the transmission 1008 may be an axle transmission or a trans axle transmission.

Alternatively, for another example, the movers and transmissions of the vehicle 1000 may output torque via a shaft to a wheel of the wheels 1014, and therein be referred to herein as wheel side movers and wheel side transmissions. A mover and a gear train may drivingly couple and output torque to the wheel side transmission, where rotary power may flow from the mover to the gear train and from the gear train to the wheel side transmission. For another example, the mover and the gear train may drivingly couple to one or more wheels of the wheels 1014. The mover and the gear train may drive one or more wheels, where rotary power may flow from the mover to the gear train and from the gear train to the one or more wheels. For example, of a wheel side configuration of vehicle 1000, the vehicle 1000 may lack an axle assembly 1012. For this example, the transmission 1008 may be a wheel side transmission and rigidly couple to a wheel of the wheels 1014 via a shaft, such as the driveshaft 1022.

In this way, the disclosed system provides for a vehicle that houses a cooling system that includes a heat exchanger electronic assembly of the present disclosure. The cooling system is a cooling circuit that may deliver coolant or another heat exchange fluid to a heat exchanger of the heat exchanger electronic assembly. The heat exchanger may be a cooler. The heat exchanger physically couples and thermally couples one or more electronics, each via a joint assembly comprising a configuration of a joint section of the present disclosure. One or more of the electronics may be power electronics such as EV inverters. The cooler is a heat exchanger that may remove thermal energy from the electronic components via the heat exchange fluid of the cooling circuit.

It will be appreciated that the configurations and routines disclosed herein are exemplary in nature, and that these specific embodiments are not to be considered in a limiting sense, because numerous variations are possible. Moreover, unless explicitly stated to the contrary, the terms “first,” “second,” “third,” and the like are not intended to denote any order, position, quantity, or importance, but rather are used merely as labels to distinguish one element from another. The subject matter of the present disclosure includes all novel and non-obvious combinations and sub-combinations of the various systems and configurations, and other features, functions, and/or properties disclosed herein.

As used herein, the term “approximately” is construed to mean plus or minus five percent of the range unless otherwise specified.

The following claims particularly point out certain combinations and sub-combinations regarded as novel and non-obvious. These claims may refer to “an” element or “a first” element or the equivalent thereof. Such claims should be understood to include incorporation of one or more such elements, neither requiring nor excluding two or more such elements. Other combinations and sub-combinations of the disclosed features, functions, elements, and/or properties may be claimed through amendment of the present claims or through presentation of new claims in this or a related application. Such claims, whether broader, narrower, equal, or different in scope to the original claims, also are regarded as included within the subject matter of the present disclosure.

1. A method for forming a thermally conductive metallurgic joint, comprising:
applying a liquid filler metal alloy comprising 76-90 wt. % gallium and 10-24 wt. % tin to a first surface and a second surface;
placing the first surface and second surface in relative positions to form an assembly; and
heating the assembly and holding the assembly at an approximately constant temperature for a non-zero duration of time to form the thermally conductive metallurgic joint.

2. The method of claim 1, wherein the metallurgic joint is joined below a temperature of 250° C., below a pressure of 20 MPa, and surrounded by an atmosphere of inert gas.

3. The method of claim 2, wherein the metallurgic joint is joined at temperatures between a range of 150° C. and 250° C.

4. The method of claim 1, wherein the liquid filler metal alloy is dispersed with a plurality of metal particles as additives during preparation, and the metal particles comprise 50 wt. %-80 wt. % of the liquid filler metal alloy after being dispersed.

5. The method of claim 1, wherein the metallurgic joint forms a singular layer of the liquid filler metal alloy of the first and second surfaces joining together, and wherein the metallurgic joint is sandwiched between the first surface and the second surface with no other materials therebetween.

6. The method of claim 1, wherein the metallurgic joint is a composite comprising a plurality of layers of liquid filler metal alloy with at least a solid metallic layer sandwiched between each layer of the liquid filler metal alloy.

7. The method of claim 6, wherein the composite is assembled via applying the liquid filler metal alloy to the first surface or the second surface as a first alloy layer, applying a first solid metallic layer to the first alloy layer, applying a second alloy layer of the liquid filler metal alloy to the first solid metallic layer, applying another solid metallic layer to a previous alloy layer of liquid filler metal alloy, and applying another alloy layer of liquid filler metal alloy to a previous solid metallic layer.

8. The method of claim 7, wherein each solid metallic layer is a metallic foil.

9. The method of claim 8, wherein the metallic foil is a copper (Cu) foil.

10. The method of claim 1, wherein an electronic component comprises the first surface and a heat exchanger comprises the second surface, the first surface being a substrate of the electronic component.

11. The method of claim 8, wherein a plurality of sealing features is around a perimeter of an area of the first surface, and the liquid filler metal alloy is applied to the area, the sealing features preventing liquid filler metal alloy from crossing the perimeter.

12. The method of claim 10, wherein the electronic component is clamped to the heat exchanger via a fixture assembly.

13. A method for physically and thermally coupling an electronic component to a heat exchanger, comprising:
fixing the heat exchanger in a position;
applying a first filler metal alloy layer of liquid filler metal alloy comprising 76-90 wt. % gallium and 10-24 wt. % tin as a first coating to a first surface of the heat exchanger;
positioning the electronic component to form an assembly and a joint section with the heat exchanger via a fixture assembly, the joint section comprising the first coating;
clamping the electronic component to the heat exchanger via the fixture assembly;
placing the fixture assembly, the electronic component, and the heat exchanger in a chamber of a heating device, the chamber having an atmosphere of inert gas;
and
joining and bonding the joint section via transient liquid phase sintering at a temperature for less than 4 hours, solidifying the joint section into metallurgic joint to thermally and physically couple the electronic component to the heat exchanger.

14. The method of claim 13, wherein the method includes applying a second coating of liquid filler metal alloy comprising 76-90 wt. % gallium and 10-24 wt. % tin to a second surface of the electronic component, and merging the second coating with the joint section during clamping of the electronic component to the heat exchanger via the fixture assembly.

15. The method of claim 13, wherein a metallic foil is fixed atop the first coating, and a second coating is applied atop the metallic foil, such that the metallic foil forms a metallic foil layer sandwiched between the first coating and the second coating.

16. The method of claim 15, wherein after a previous coating of filler metal alloy is applied, another metallic foil is fixed atop the previous coating, and another coating of filler metal alloy is applied atop the another metallic foil, such that the another metallic foil is sandwiched between the previous coating and the another coating.

17. A heat exchanger electronic assembly, comprising:
a heat exchanger, comprising a first parent layer comprising a first metal;
at least an electronic component, comprising a second parent layer comprising a second metal;
a joint section, the joint section comprising at least a layer of filler metal alloy, the filler metal alloy between a first surface of the first parent layer and a second surface of the second parent layer;
where the joint section is a metallurgic joint section that metallurgically bonds the first parent layer to the second parent layer, physically coupling and thermally coupling the heat exchanger to the electronic component, and the joint section is 50 wt. %-80 wt. % copper, 20 wt. %-50 wt. % gallium, and up to 10 wt. % tin after solidification and joining of the joint section to the first parent layer and second parent layer.

18. The heat exchanger electronic assembly of claim 17, wherein the joint section comprises a plurality of filler metal alloy layers and at least a metallic foil layer, where the metallic foil layer is interleaved and sandwiched between filler metal alloy layers.

19. The heat exchanger electronic assembly of claim 17, wherein the filler metal alloy includes a plurality of metal particles as additives, the metal particles comprise copper, each of the metal particles has a diameter less than 50 microns, and the metal particles comprise 50 wt. %-80 wt. % of the filler metal alloy after being dispersed.

20. The heat exchanger electronic assembly of claim 17, wherein the first metal and the second metal are the same.
